(19) United States
(12) Patent Application Publication
(10) Pub. No.: US 2026/0352233 A1
(43) Pub. Date: Nov. 5, 2026

(54) RANK CONDITION FOR LOW-DENSITY PARITY CHECK CODES

(71) Applicant: QUALCOMM Incorporated, San Diego, CA (US)

(72) Inventors: Pinar SEN, San Diego, CA (US); Wei YANG, San Diego, CA (US); Jing JIANG, San Diego, CA (US)

(21) Appl. No.: 19/660,451

(22) Filed: Apr. 28, 2026

Related U.S. Application Data
(60) Provisional application No. 63/798,881, filed on May 2, 2025.

(51) Int. Cl. H03M 13/11

(52) U.S. Cl. CPC H03M 13/1171

(57) ABSTRACT

Various aspects of the present disclosure generally relate to wireless communication. In some aspects, a wireless communication device may encode, using a low-density parity check (LDPC) code, a communication to obtain an encoded communication, the LDPC code being associated with a base graph that is associated with a systematic matrix and a parity matrix, and both the systematic matrix and the parity matrix satisfying a rank condition. The wireless communication device may provide the encoded communication. Numerous other aspects are described.

### CROSS-REFERENCE TO RELATED APPLICATION

This Patent Application claims priority to U.S. Provisional Patent Application No. 63/798,881, filed on May 2, 2025, entitled “RANK CONDITION FOR LOW-DENSITY PARITY CHECK CODES,” and assigned to the assignee hereof. The disclosure of the prior Application is considered part of and is incorporated by reference into this Patent Application.

### INTRODUCTION

Aspects of the present disclosure generally relate to wireless communication and specifically relate to techniques, apparatuses, and methods associated with conditions for channel coding.

Wireless communication systems are widely deployed to provide various services, which may involve carrying or supporting voice, text, other messaging, video, data, or other traffic. Typical wireless communication systems may employ multiple-access radio access technologies (RATs) capable of supporting communication among multiple wireless communication devices including user devices or other devices by sharing the available system resources (for example, time domain resources, frequency domain resources, spatial domain resources, or device transmit power, among other examples). Such multiple-access RATs are supported by technological advancements that have been adopted in various telecommunication standards, which define common protocols that enable different wireless communication devices to communicate on a local, municipal, national, regional, or global level. An example telecommunication standard is New Radio (NR). NR, which also may be referred to as 5G, is part of a continuous mobile broadband evolution promulgated by the Third Generation Partnership Project (3GPP). As the demand for connectivity continues to increase, further improvements in NR may be implemented, and other RATs, such as 6G and beyond, may be introduced to enable new applications and facilitate new use cases.

### SUMMARY

Some aspects described herein relate to an apparatus at a first wireless communication device. The apparatus may include one or more memories and one or more processors coupled with the one or more memories. The one or more processors may be configured to cause the first wireless communication device to encode, using a low-density parity check (LDPC) code, a communication to obtain an encoded communication, wherein the LDPC code is associated with a base graph that is associated with a systematic matrix and a parity matrix, and both the systematic matrix and the parity matrix satisfy a rank condition. The one or more processors may be configured to cause the first wireless communication device to provide, to a second wireless communication device, the encoded communication.

Some aspects described herein relate to an apparatus at a first wireless communication device. The apparatus may include one or more memories and one or more processors coupled with the one or more memories. The one or more processors may be configured to cause the first wireless communication device to obtain, from a second wireless communication device, an encoded communication. The one or more processors may be configured to cause the first wireless communication device to decode, using an LDPC code, the encoded communication to obtain a communication, wherein the LDPC code is associated with a base graph that is associated with a systematic matrix and a parity matrix, and both the systematic matrix and the parity matrix satisfy a rank condition.

Some aspects described herein relate to a method of wireless communication performed at a first wireless communication device. The method may include encoding, using an LDPC code, a communication to obtain an encoded communication, the LDPC code being associated with a base graph that is associated with a systematic matrix and a parity matrix, and both the systematic matrix and the parity matrix satisfying a rank condition. The method may include providing, to a second wireless communication device, the encoded communication.

Some aspects described herein relate to a method of wireless communication performed at a first wireless communication device. The method may include obtaining, from a second wireless communication device, an encoded communication. The method may include decoding, using an LDPC code, the encoded communication to obtain a communication, the LDPC code being associated with a base graph that includes a systematic matrix and a parity matrix, and both the systematic matrix and the parity matrix satisfying a rank condition.

Some aspects described herein relate to a non-transitory computer-readable medium storing a set of instructions for wireless communication includes one or more instructions. The one or more instructions, when executed by one or more processors of a wireless communication device, may cause the wireless communication device to encode, using an LDPC code, a communication to obtain an encoded communication, the LDPC code being associated with a base graph that is associated with a systematic matrix and a parity matrix, and both the systematic matrix and the parity matrix satisfying a rank condition. The one or more instructions, when executed by one or more processors of a wireless communication device, may cause the wireless communication device to provide, to a second wireless communication device, the encoded communication.

Some aspects described herein relate to a non-transitory computer-readable medium storing a set of instructions for wireless communication includes one or more instructions. The one or more instructions, when executed by one or more processors of a wireless communication device, may cause the wireless communication device to obtain, from a second wireless communication device, an encoded communication. The one or more instructions, when executed by one or more processors of a wireless communication device, may cause the wireless communication device to decode, using an LDPC code, the encoded communication to obtain a communication, the LDPC code being associated with a base graph that includes a systematic matrix and a parity matrix, and both the systematic matrix and the parity matrix satisfying a rank condition.

Some aspects described herein relate to an apparatus for wireless communication. The apparatus may include means for encoding, using an LDPC code, a communication to obtain an encoded communication, the LDPC code being associated with a base graph that is associated with a systematic matrix and a parity matrix, and both the systematic matrix and the parity matrix satisfying a rank condition. The apparatus may include means for providing the encoded communication.

Some aspects described herein relate to an apparatus for wireless communication. The apparatus may include means for obtaining an encoded communication. The apparatus may include means for decoding, using an LDPC code, the encoded communication to obtain a communication, the LDPC code being associated with a base graph that includes a systematic matrix and a parity matrix, and both the systematic matrix and the parity matrix satisfying a rank condition.

Some aspects described herein relate to an apparatus at a first wireless communication device. The apparatus may include one or more memories and one or more processors coupled with the one or more memories. The one or more processors may be configured to cause the first wireless communication device to encode, using a low-density parity check (LDPC) code, a communication to obtain an encoded communication, wherein the LDPC code is associated with a base graph that is associated with a systematic matrix and a parity matrix, both the systematic matrix and the parity matrix satisfy a rank condition, and the parity matrix is full rank over a Galois field. The one or more processors may be configured to cause the first wireless communication device to provide, to a second wireless communication device, the encoded communication.

Some aspects described herein relate to an apparatus at a first wireless communication device. The apparatus may include one or more memories and one or more processors coupled with the one or more memories. The one or more processors may be configured to cause the first wireless communication device to obtain, from a second wireless communication device, an encoded communication. The one or more processors may be configured to cause the first wireless communication device to decode, using an LDPC code, the encoded communication to obtain a communication, wherein the LDPC code is associated with a base graph that is associated with a systematic matrix and a parity matrix, both the systematic matrix and the parity matrix satisfy a rank condition, and the parity matrix is full rank over a Galois field.

Some aspects described herein relate to a method of wireless communication performed at a first wireless communication device. The method may include encoding, using an LDPC code, a communication to obtain an encoded communication, the LDPC code being associated with a base graph that is associated with a systematic matrix and a parity matrix, and the systematic matrix and the parity matrix satisfying a rank condition, and the parity matrix is full rank over a Galois field. The method may include providing, to a second wireless communication device, the encoded communication.

Some aspects described herein relate to a method of wireless communication performed at a first wireless communication device. The method may include obtaining, from a second wireless communication device, an encoded communication. The method may include decoding, using an LDPC code, the encoded communication to obtain a communication, the LDPC code being associated with a base graph that includes a systematic matrix and a parity matrix, both the systematic matrix and the parity matrix satisfying a rank condition, and the parity matrix is full rank over a Galois field.

Some aspects described herein relate to a non-transitory computer-readable medium storing a set of instructions for wireless communication includes one or more instructions. The one or more instructions, when executed by one or more processors of a wireless communication device, may cause the wireless communication device to encode, using an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field. The one or more instructions, when executed by one or more processors of a wireless communication device, may cause the wireless communication device to provide, to a second wireless communication device, the encoded communication.

Some aspects described herein relate to a non-transitory computer-readable medium storing a set of instructions for wireless communication includes one or more instructions. The one or more instructions, when executed by one or more processors of a wireless communication device, may cause the wireless communication device to obtain, from a second wireless communication device, an encoded communication. The one or more instructions, when executed by one or more processors of a wireless communication device, may cause the wireless communication device to decode, using an LDPC code, the encoded communication to obtain a communication, the LDPC code being associated with a base graph that includes a systematic matrix and a parity matrix, both the systematic matrix and the parity matrix satisfying a rank condition, and the parity matrix is full rank over a Galois field.

Some aspects described herein relate to an apparatus for wireless communication. The apparatus may include means for encoding, using an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field. The apparatus may include means for providing the encoded communication.

Some aspects described herein relate to an apparatus for wireless communication. The apparatus may include means for obtaining an encoded communication. The apparatus may include means for decoding, using an LDPC code, the encoded communication to obtain a communication, the LDPC code being associated with a base graph that includes a systematic matrix and a parity matrix, both the systematic matrix and the parity matrix satisfying a rank condition, and the parity matrix is full rank over a Galois field.

The systems, methods, and devices of this disclosure each have several innovative aspects, no single one of which is solely responsible for the desirable attributes disclosed herein.

Aspects of the present disclosure may generally be implemented by or as a method, apparatus, system, computer program product, non-transitory computer-readable medium, user equipment, network node, wireless communication device, or processing system as substantially described in the Detailed Description with reference to, and as illustrated by, the accompanying drawings. Details of one or more implementations of the subject matter described in this disclosure are set forth in the accompanying drawings and the description below. Other features, aspects, and advantages will become apparent from the description, the drawings, and the claims. Note that the relative dimensions of the following figures may not be drawn to scale.

### BRIEF DESCRIPTION OF THE DRAWINGS

FIG. 1 is a diagram illustrating an example of a wireless communication network.

FIG. 2 is a diagram illustrating an example of communication using low-density parity check (LDPC) codes.

FIGS. 3A and 3B are diagrams illustrating an example of an LDPC base graph matrix and an LDPC base graph.

FIG. 4 is a diagram illustrating an example of a parity check matrix associated with an LDPC code.

FIG. 5 is a diagram illustrating an example of a base graph that supports fast converging LDPC techniques.

FIG. 6 is a diagram illustrating an example associated with a rank condition for LDPC codes.

FIG. 7 is a diagram illustrating an example of a base graph matrix that satisfies a rank condition for LDPC codes.

FIGS. 8A-8C are diagrams illustrating an example of a base graph matrix that satisfies a rank condition for LDPC codes.

FIG. 9 is a diagram illustrating an example process performed, for example, at a wireless communication device or an apparatus of a wireless communication device.

FIG. 10 is a diagram illustrating an example process performed, for example, at a wireless communication device or an apparatus of a wireless communication device.

FIG. 11 is a diagram of an example apparatus for wireless communication.

FIG. 12 is a diagram illustrating an example of a hardware implementation for an apparatus employing a processing system.

FIG. 13 is a diagram illustrating an example of an implementation of code and circuitry for an apparatus.

FIG. 14 is a diagram of an example apparatus for wireless communication.

FIG. 15 is a diagram illustrating an example of a hardware implementation for an apparatus employing a processing system.

FIG. 16 is a diagram illustrating an example of an implementation of code and circuitry for an apparatus.

### DETAILED DESCRIPTION

In some examples, to support use cases that may demand high data rates, high reliability, low latency, or low power consumption, channel coding may be used in a wireless communication system to ensure reliable and efficient communication. For example, channel coding may involve an encoding operation performed at a transmitter to add redundancy to transmitted data, and a decoding operation at a receiver where the additional redundancy is used to detect or correct errors that may occur during transmission or reception. For example, because wireless communication channels may be noisy or unreliable, data can be corrupted during transmission due to factors, such as noise, interference, or channel fading, among other examples. When errors in transmitted data cannot be corrected at the receiver, the transmitted data may be lost or retransmissions may be performed to provide the correct data to the receiver. Accordingly, because lost data reduces reliability and retransmissions increase latency and power consumption, channel coding techniques are used in wireless communication systems to ensure that received data is the same as transmitted data. For example, channel coding techniques may use polar codes, Reed-Muller codes, repetition codes, or simplex codes for control channels or other channels with low to moderate payload sizes. Channel coding techniques may use turbo codes or low density parity check (LDPC) codes for data channels or other channels that tend to have relatively larger payload sizes.

In this way, channel coding techniques may offer various performance improvements in wireless communication systems. For example, channel coding techniques provide error detection and error correction capabilities that may increase a likelihood that transmitted data is reliably received despite noise, interference, or fading conditions that may be present in a wireless channel. In addition, channel coding may reduce an error rate and increase reliability for wireless transmission, which may mitigate errors, reduce retransmissions, and improve overall throughput. Furthermore, although encoding and decoding operations may add some processing delay, efficient channel coding schemes may reduce the processing delay and the improved error detection and correction capabilities may reduce retransmissions, which reduces overall latency. Channel coding techniques may also extend wireless coverage because a transmitter may transmit data in a reliable manner over a longer distance or in a challenging radio environment, may improve spectral efficiency by minimizing the impact that errors have on the use of available frequency spectrum, or may improve energy efficiency at network nodes and user devices by supporting efficient encoding or decoding schemes or reducing retransmissions, among other examples.

LDPC codes are linear block codes that may be used to provide forward error correction capabilities in a communication system with a performance that approaches channel capacity. The performance may be achieved under an iterative belief propagation decoding scheme, also known as message-passing decoding, which has a linear complexity associated with an LDPC code block length. In particular, LDPC codes may be defined or represented according to a sparse parity check matrix (PCM) that typically has a low density of entries with a value of one. For example, the PCM may be “sparse” in that the PCM may include a relatively high quantity of entries with a value of zero. From a transmitter perspective, the transmitter (or LDPC encoder) may multiply one or more systematic bits by a PCM to generate a code block (or codeword). A codeword may include one or more systematic bits and one or more parity bits. Systematic bits may sometimes be referred to as information bits. The sparse PCM generally includes a systematic matrix and a parity matrix. The systematic matrix may sometimes be referred to as a “systematic submatrix” and the parity matrix may sometimes be referred to as a “parity submatrix.” The systematic matrix may be a portion of the PCM or a base graph matrix that includes information used to encode systematic bits of a communication. The parity matrix may be inverted to compute a parity vector used to encode an LDPC code. In some cases, an LDPC code may be quasi-cyclic. For example, a quasi-cyclic LDPC (QC-LDPC) code may be associated with a base graph and lifting values that provide a compact PCM representation, which enables efficient encoding and high parallelism in a decoder architecture.

The structure of a QC-LDPC code may be defined by a base graph and a lifting operation that transforms the base graph into a larger, more complex graph suitable for practical use. The base graph may be a graph that is used as the basis for constructing the larger graph, which may be a PCM for the LDPC code. The base graph may represent one or more macroscopic properties of the LDPC code, such as a signal-to-noise ratio (SNR) threshold required to achieve a given error rate. The base graph may indicate connectivity between variable nodes and check nodes. A variable node may represent one or more codeword bits, which may include systematic bits or parity bits. A check node may represent one or more parity constraints. The base graph may be represented as a base graph matrix in which columns of the base graph matrix represent respective variable nodes and rows of the base graph matrix represent respective check nodes. An entry in the base graph matrix with a value of one may indicate that a variable node is connected to a check node in the base graph, where the variable node is associated with the column of the entry and the check node is associated with the row of the entry. A “connection” between a variable node and a check node may also be referred to as an “edge.” A connection between a variable node and a check node in an LDPC code represents a parity-check constraint, indicating that the value of the variable node contributes to the parity-check equation defined by the check node.

The lifting operation may include expanding the base graph by a factor, sometimes referred to as a “lift value.” The lifting operation may result in a lifted graph or PCM, which may be used in the encoding and decoding processes. As part of the lifting operation, each entry in the base graph may be replaced by a circulant matrix. The circulant matrix may be an identity matrix that is cyclically shifted by a given cyclic shift. The identify matrix may have a size of Z×Z, where Z is the lift value. The lifting operation may preserve the degree distribution for each coded bit. Each variable node in the base graph may be associated with Z coded bits from the LDPC code. A degree of a variable node may be a quantity of check nodes that the variable node is connected to in the base graph.

In some examples, the LDPC code may be a systematic LDPC code in which the coded bits generated using the LDPC code includes the original information bits followed by additional parity bits. In this structure, the information bits may be transmitted in their original form, making it easier for the receiver to obtain the original data directly if no errors occur. The parity bits may be generated through linear combinations of the information bits based on the PCM (or lifted graph) of the LDPC code. This systematic arrangement may simplify the encoding process and may enable more efficient error detection and correction during the decoding process, because the receiver can directly verify the integrity of the information bits against the parity bits.

For systematic LDPC codes, the PCM of the LDPC code may include a systematic matrix and a parity matrix. In some examples, to ensure that the LDPC code can uniquely represent each possible codeword and provide effective error correction, there may be a requirement that both the systematic matrix and a parity matrix of the PCM be full rank over a Galois field of order two. In this context, “rank” refers to a quantity of linearly independent rows or columns in a matrix, indicating the dimension of the vector space spanned by its rows or columns. “Full rank” refers to a scenario in which a rank of a matrix is equal to (or less than) the lesser of the quantity of rows or columns in the matrix. A full rank PCM may ensure that the system of linear equations defined by the parity-check constraints indicated by the PCM has a unique solution for each set of information bits. This uniqueness may ensure that the encoded data can be reliably decoded back to the original information bits without ambiguity. For example, if the PCM were not full rank, some codewords may be linearly dependent, leading to potential decoding errors and reduced error correction performance, ultimately reducing the reliability and efficiency of the wireless communication system. For example, linearly dependent codewords may result in decoding errors because multiple different sets of information bits could produce the same coded bits, increasing the difficulty for the receiver to determine the original information bits from the received data. This ambiguity reduces the error correction capability of the LDPC code because the receiver may be unable to distinguish between different transmitted messages (e.g., if two or more sets of information bits produce the same coded bits), increasing the likelihood of incorrect or failed decoding.

In some examples, one or more new base graphs may be defined, configured, or otherwise fixed, such as by the Third Generation Partnership Project (3GPP). For example, a base graph may include one or more punctured nodes. “Punctured node” refers to a variable node whose associated coded bits are not transmitted by a transmitter. The coded bits associated with the punctured node may be inferred by a receiver using received coded bits during the decoding process. As a result, having the one or more punctured nodes may reduce the code rate of the LDPC code which maintain error correction capabilities. In some examples, the one or more punctured nodes having a larger degree may improve asymptotic performance for the LDPC codes. Asymptotic performance may refer to the behavior and effectiveness of an error-correcting code, such as the LDPC code, as the block length (the number of bits in a codeword) approaches infinity, indicating how well the LDPC code performs in terms of error correction and reliability under long-term conditions. To increase the degree of the one or more punctured nodes, some base graphs may include two or more punctured nodes, such as the base graph 1 (BG1) defined, or otherwise fixed, by the 3GPP.

However, having multiple punctured nodes in the base graph may increase a convergence time associated with the decoding process. For example, having multiple punctured nodes in the base graph may increase the amount of unknown information at the receiver because the transmitter does not transmit the coded bits associated with the multiple punctured nodes. Therefore, the receiver may perform a relatively high quantity of decoding iterations in order to reach a reasonable reliability level for the coded bits associated with the multiple punctured nodes. The relatively high quantity of decoding iterations may increase the convergence time associated with the decoding process, or consume processing resources associated with the receiver performing the decoding process, among other examples.

Therefore, in some examples, a base graph may include a single punctured node. The base graph including a single punctured node may reduce the convergence time associated with the decoding process. In some examples, the single punctured node may be connected to a given check node via multiple connections or edges. This type of connection may be referred to as a parallel edge, a double edge, or a multi-edge, among other examples. For example, this type of connection may be represented in a base graph entry by a value of two or higher to indicate that quantity of connections between the punctured node and the given check node. As a result, in some examples, the base graph matrix may be a non-binary matrix. A “non-binary” matrix refers to a matrix that has entries that include numeric values other than zero or one. A “binary” matrix refers to a matrix that only has entries having numeric values of zero or one. Having the single punctured node may be connected to a given check node via multiple connections or edges may increase the degree of the punctured node, thereby improving the asymptotic performance for the LDPC codes.

In other examples, a new base graph may be defined, configured, or otherwise fixed, for other purposes. As new base graphs are defined configured, or otherwise fixed, it may be difficult to ensure that PCMs that are generated by the new base graphs satisfy the full rank condition for systematic matrices and parity matrices included in the PCMs. For example, because parameters of a lifting operation may be variable and change over time, there may be a risk that a base graph results in a PCM that is not full rank when using certain parameters of the lifting operation, such as certain lift values or cyclic shifts. A transmitter and receiver performing a channel coding operation using a PCM that is not full rank may increase the likelihood of decoding errors at the receiver because the non-full-rank PCM may result in codewords that are linearly dependent. The increased likelihood of decoding errors may reduce performance, reliability, or throughout, among other examples, for communications that encoded using the LDPC codes.

Various aspects relate generally to an LDPC code in a wireless communication system. Some aspects more specifically relate to a first wireless communication device and a second wireless communication device communicating one or more communications that are encoded or decoded using the LDPC code. In some aspects, the LDPC code may be based on a base graph that satisfies or meets a rank condition. For example, the base graph may be configured to meet the rank condition. The rank condition may be that a systematic matrix and a parity matrix of the base graph matrix, that represents the base graph, are both full rank over the Galois field of order two. The rank of the matrices may be evaluated over the Galois field of order two because LDPC codes may be binary codes that operate over binary fields that use values of zero or one. In some aspects, the base graph may include one or more variable nodes or punctured nodes that are connected to a check node via multiple edges. For example, the base graph matrix may be a non-binary matrix. In such examples, the rank condition may indicate that a binary version of the systematic matrix be full rank over the Galois field of order two and that a binary version of the parity matrix be full rank over the Galois field of order two. For example, the base graph may be a foundational blueprint for designing the LDPC codes. For the base graph to be effective, the base graph may satisfy the rank condition which ensures that the LDPC codes can accurately detect and correct errors. In some aspects, the rank condition may require the base graph to be complete and capable of representing all possible data transmissions without ambiguity. For example, the rank condition may indicate that both the systematic matrix and the parity matrix are full rank. A matrix, such as systematic matrix or the parity matrix, may be full rank if the rank of the matrix is equal to the lesser of the quantity of rows or quantity of columns in the matrix. The rank of the matrix may be the quantity of independent rows or columns included in the matrix, indicating the amount of unique information that the matrix can represent. The rank of the matrix may be determined by counting the quantity of rows or columns that are not simple multiples of each other. Such rows or columns may add unique information to the matrix.

In some aspects, the base graph matrix may include one or more entries with a value greater than one, indicating the multiple edges between a given variable node and a given check node. The one or more entries may be set to a value of zero in a modified version of the base graph. The rank condition may be verified using the modified base graph matrix. As another example, the rank condition may indicate that a modulo two value of a determinant of the parity matrix is to be one. The modulo two value of the determinant of the parity matrix being one may indicate that the parity matrix is invertible over Galois field of order two, which ensures that the parity matrix is full rank. For example, the modulo two value of the determinant of the parity matrix being one may indicate that the parity matrix has no linear dependencies among rows or columns, meaning that all rows or columns are linearly independent.

During an encoding operation, the first wireless communication device may generate a PCM using the base graph and one or more parameters of a lifting operation, such as a lift value and one or more cyclic shift values. The first wireless communication device may encode a communication using the PCM to generate an encoded communication that includes one or more coded bits. The first wireless communication device may provide or transmit, and the second wireless communication device may obtain or receive, the encoded communication. During a decoding operation, the second wireless communication device may generate a PCM using the base graph and one or more parameters of a lifting operation, such as a lift value and one or more cyclic shift values. The second wireless communication device may decode the encoded communication using the PCM.

By the first wireless communication device and the second wireless communication device encoding or decoding communications using a PCM that is based on the base graph that satisfies the rank condition, the described techniques may ensure that the PCM is full rank over the Galois field of two regardless of the lifting parameters used to generate the PCM. This may reduce the complexity associated with ensuring that the PCM is full rank as new base graphs are configured or designed. By ensuring that the PCM is full rank as a result of the base graph satisfying the rank condition, the described techniques may reduce the risk of the first wireless communication device mapping different sets of information bits to the same codeword. This reduces the risk of decoding errors of the LDPC code at the second wireless communication device that would have otherwise been caused by the first wireless communication device mapping different sets of information bits to the same codeword as a result of using a PCM that is not full rank. As a result, by applying the rank condition at the base graph level, the described techniques may improve decoding performance when using LDPC codes by ensuring that the PCM of the LDPC code is full rank. Improving the decoding performance may increase the reliability, throughput, or performance of communications that are encoded using the LDPC code.

Additionally, by applying the rank condition at the base graph level, the design process may be simplified because the base graph satisfying the rank condition may ensure that the PCM or the lifted graph will be full rank without requiring further adjustments during the lifting process. This improves the efficiency of the design and implementation of LDPC codes. Additionally, this reduces the complexity for the implementation of new base graphs, such as base graphs with a single punctured node or base graphs with multiple edges, such as those represented by a non-binary base graph matrix.

5G New Radio (NR) may support enhanced mobile broadband (eMBB) access, Internet of Things (IoT) networks or reduced capability (RedCap) device deployments, ultra-reliable low-latency communication (URLLC) applications, or massive machine-type communication (mMTC), among other examples. To support these and other target verticals, a wireless communication system may be designed to implement a modularized functional infrastructure, a disaggregated and service-based network architecture, network function virtualization, network slicing, multi-access edge computing, millimeter wave (mmWave) technologies including massive multiple-input multiple-output (MIMO), beamforming, IoT device or RedCap device connectivity and management, industrial connectivity, licensed and unlicensed spectrum access, sidelink and other device-to-device direct communication (for example, cellular vehicle-to-everything (CV2X) communication), frequency spectrum expansion, overlapping spectrum use, small cell deployments, non-terrestrial network (NTN) deployments, device aggregation, advanced duplex communication (for example, sub-band full-duplex (SBFD)), multiple-subscriber implementations, high-precision positioning, radio frequency (RF) sensing, network energy savings (NES), low-power signaling and radios, or artificial intelligence or machine learning (AI/ML), among other examples.

The foregoing and other technological improvements may support use cases, such as wireless fronthauls, wireless midhauls, wireless backhauls, wireless data centers, extended reality (XR) and metaverse applications, meta services for supporting vehicle connectivity, holographic and mixed reality communication, autonomous and collaborative robots, vehicle platooning and cooperative maneuvering, sensing networks, gesture monitoring, human-brain interfacing, digital twin applications, asset management, and universal coverage applications using non-terrestrial or aerial platforms, among other examples.

The methods, operations, apparatuses, and techniques described herein may enable one or more of the foregoing technologies or new technologies or support one or more of the foregoing use cases or new use cases.

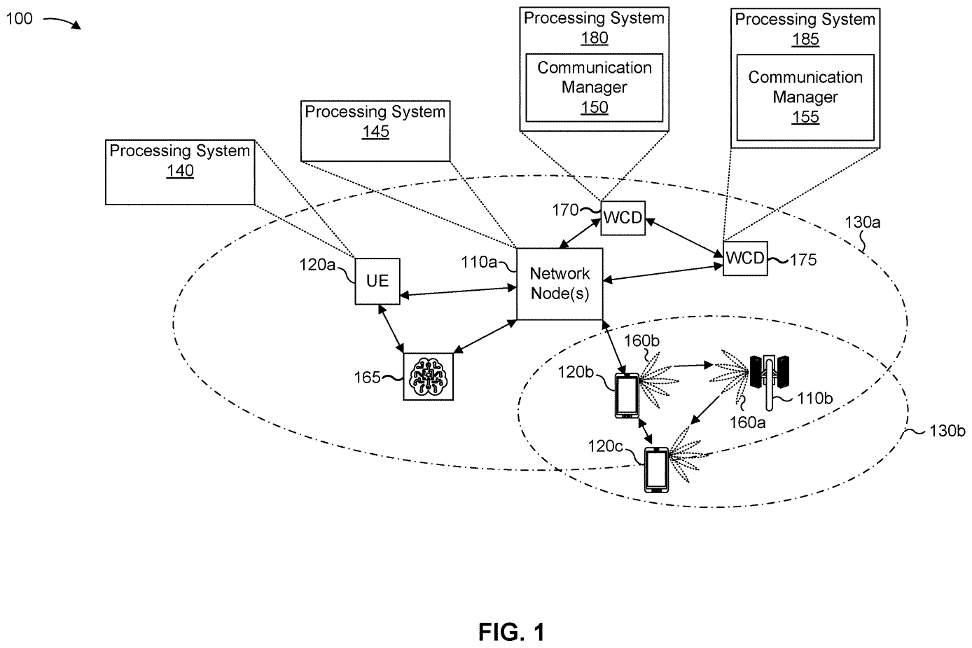

FIG. 1 is a diagram illustrating an example of a wireless communication network 100. The wireless communication network 100 may be or may include elements of a 5G network or a 6G network, among other examples. The wireless communication network 100 may include multiple network nodes 110. For example, in FIG. 1, the wireless communication network 100 includes multiple network nodes 110, including a network node 110a and a network node 110b (each of which also may be referred to herein simply as a “network node 110”). The network nodes 110 may support communications with multiple user equipment (UEs) 120. For example, in FIG. 1, the network nodes 110 support communication with a UE 120a, a UE 120b, and a UE 120c (each of which also may be referred to herein simply as a “UE 120”). In some examples, a UE 120 also may communicate with other UEs 120 and a network node 110 also may communicate with a core network and with other network nodes 110.

The network nodes 110 and the UEs 120 of the wireless communication network 100 communicate using the electromagnetic spectrum, which may be subdivided into various licensed or unlicensed operating bands, frequency ranges, component carriers, or channels that define associated frequencies available for communications. In some examples, each of the network nodes 110 and the UEs 120 may communicate using one or multiple component carriers in one or more operating bands or ranges. Typically, various operating bands are defined as frequency range designations FR1 (410 MHz through 7.125 GHz), FR 2 (24.25 GHz through 52.6 GHz), FR3 (7.125 GHz through 24.25 GHz), FR4a or FR4-1 (52.6 GHz through 71 GHz), FR4 (52.6 GHz through 114.25 GHz), and FR5 (114.25 GHz through 300 GHz). Although a portion of FR1 is greater than 6 GHz, FR1 is often referred to (interchangeably) as a “sub-6 GHz” band in some documents and articles. Similarly, FR2 is often referred to (interchangeably) as a “millimeter wave” band in some documents and articles.

A network node 110 or a UE 120 may include one or more devices, components, or systems that enable communication with other devices, components, or systems of the wireless communication network 100. For example, a UE 120 and a network node 110 may each include one or more chips, system-on-chips (SoCs), chipsets, packages, or devices that individually or collectively constitute or comprise a processing system. As shown in FIG. 1, each UE 120 includes a processing system 140 and each network node 110 includes a processing system 145. A processing system (for example, the processing system 140 or the processing system 145) includes processor (or “processing”) circuitry in the form of one or multiple processors, microprocessors, processing units (such as central processing units (CPUs), graphics processing units (GPUs), neural processing units (NPUs) (also referred to as neural network processors or deep learning processors (DLPs)), or digital signal processors (DSPs)), processing blocks, application-specific integrated circuits (ASICs), programmable logic devices (PLDs), or other discrete gate or transistor logic or circuitry (any one or more of which may be generally referred to herein individually as a “processor” or collectively as “the processor” or “the processor circuitry”). Such processors may be individually or collectively configurable or configured to perform various functions or operations described herein. A group of processors collectively configurable or configured to perform a set of functions may include a first processor configurable or configured to perform a first function of the set and a second processor configurable or configured to perform a second function of the set. In some other examples, each of a group of processors may be configurable or configured to perform a same set of functions.

The processing system 140 and the processing system 145 may each include memory circuitry in the form of one or multiple memory devices, memory blocks, memory elements, or other discrete gate or transistor logic or circuitry, each of which may include or implement tangible storage media, such as random-access memory, or read-only memory, or combinations thereof (any one or more of which may be generally referred to herein individually as a “memory” or collectively as “the memory” or “the memory circuitry”). One or more of the memories may be coupled (for example, operatively coupled, communicatively coupled, electronically coupled, or electrically coupled) with one or more of the processors. One or more of the memories may individually or collectively store processor-executable code or instructions (such as software) (for example, which may be referred to as “one or more code-storing memories” or “code-storing memory circuitry”). For example, “code-storing memory” or “code-storing memory circuitry” refers to memory (or memory circuitry) that is configured to store processor-executable code or instructions. The processor-executable code or instructions, when executed by one or more of the processors, may configure one or more of the processors (or processing circuitry) to perform various functions or operations described herein. Additionally, or alternatively, in some examples, one or more of the processors may be configured to perform various functions or operations described herein without requiring configuration by software. Software shall be construed broadly to mean instructions, instruction sets, code, code segments, program code, programs, subprograms, software modules, applications, software applications, software packages, routines, subroutines, objects, executables, threads of execution, procedures, or functions, among other examples, whether referred to as software, firmware, middleware, microcode, hardware description language, or otherwise.

The processing system 140 and the processing system 145 may each include or be coupled with one or more modems (such as a cellular (for example, a 5G or 6G compliant) modem). In some examples, one or more processors of the processing system 140 or the processing system 145 may include or implement one or more of the modems. The processing system 140 and the processing system 145 also may include or be coupled with multiple radios (collectively “the radio”), multiple RF chains, or multiple transceivers, each of which may in turn be coupled with one or more of multiple antennas. In some examples, one or more processors of the processing system 140 or the processing system 145 may include or implement one or more of the radios, RF chains, or transceivers. An RF chain may include one or more filters, mixers, oscillators, amplifiers, analog-to-digital converters (ADCs), or other devices that convert between an analog signal (such as for transmission or reception via an air interface) and a digital signal (such as for processing by the processing system 140 or by the processing system 145).

A network node 110 and a UE 120 may each include one or multiple antennas or antenna arrays. Typical network nodes 110 and UEs 120 may include multiple antennas, which may be organized or structured into one or more antenna panels, one or more antenna groups, one or more sets of antenna elements, or one or more antenna arrays, among other examples. As used herein, the term “antenna” can refer to one or more antennas, one or more antenna panels, one or more antenna groups, one or more sets of antenna elements, or one or more antenna arrays. The term “antenna panel” can refer to a group of antennas (such as antenna elements) arranged in an array or panel, which may facilitate beamforming by manipulating parameters associated with the group of antennas. The term “antenna module” may refer to circuitry including one or more antennas as well as one or more other components (such as filters, amplifiers, or processors) associated with integrating the antenna module into a wireless communication device, such as the network node 110 and the UE 120.

A network node 110 may be, may include, or also may be referred to as an NR network node, a 5G network node, a 6G network node, a Node B, a gNB, an access point (AP), a transmission reception point (TRP), a network entity, a network element, a network equipment, or another type of device, component, or system included in a radio access network (RAN). In various deployments, a network node 110 may be implemented as a single physical node (for example, a single physical structure) or may be implemented as two or more physical nodes (for example, two or more distinct physical structures). For example, a network node 110 may be a device or system that implements a part of a radio protocol stack, a device or system that implements a full radio protocol stack (such as a full gNB protocol stack), or a collection of devices or systems that collectively implement the full radio protocol stack. For example, and as shown, a network node 110 may be an aggregated network node having an aggregated architecture, meaning that the network node 110 may implement a full radio protocol stack that is physically and logically integrated within a single physical structure in the wireless communication network 100. For example, an aggregated network node 110 may include a single standalone base station or a single TRP that operates with a full radio protocol stack to enable or facilitate communication between a UE 120 and a core network of the wireless communication network 100.

Alternatively, a network node 110 may be a disaggregated network node 110 (sometimes referred to as a disaggregated base station), having a disaggregated architecture, meaning that the network node 110 may operate with a radio protocol stack that is physically distributed or logically distributed among two or more nodes in the same geographic location or in different geographic locations. In some deployments, disaggregated network nodes 110 may be used in an integrated access and backhaul (IAB) network, in an open radio access network (O-RAN) (such as a network configuration in compliance with the O-RAN Alliance), or in a virtualized radio access network (vRAN), also known as a cloud radio access network (C-RAN), to facilitate scaling by separating network functionality into multiple units or modules that can be individually deployed.

The disaggregated network nodes 110 of the wireless communication network 100 may include one or more central units (CUs), one or more distributed units (DUs), and one or more radio units (RUs). A CU may host one or more higher layers, such as a radio resource control (RRC) layer, a packet data convergence protocol (PDCP) layer, and a service data adaptation protocol (SDAP) layer, among other examples. A CU can communicate with a core network either directly (for example, via a backhaul link) or indirectly (for example, via one or more disaggregated control units, such as a non-real-time (Non-RT) RAN intelligent controller (RIC) associated with a Service Management and Orchestration (SMO) framework or a near-real-time (Near-RT) RIC). A DU may host one or more of a radio link control (RLC) layer, a medium access control (MAC) layer, or one or more higher physical (PHY) layers depending, at least in part, on a functional split, such as a functional split defined by the 3GPP. In some examples, a DU also may host a lower PHY layer that is configured to perform functions, such as a fast Fourier transform (FFT), an inverse FFT (IFFT), beamforming, or physical random access channel (PRACH) extraction and filtering, among other examples. An RU may perform RF processing functions or lower PHY layer functions, such as an FFT, an IFFT, beamforming, or PRACH extraction and filtering, among other examples, according to a functional split, such as a lower layer split (LLS). In such an architecture, each RU can be operated to handle over the air (OTA) communication with one or more UEs 120. A CU may communicate with one or more DUs via respective midhaul links, such as via F1 interfaces. Each of the DUs may communicate with one or more RUs via respective fronthaul links. Each of the RUs may communicate with one or more UEs 120 via respective RF access links. In some deployments, a UE 120 may be simultaneously served by multiple RUs.

In some examples, a single network node 110 may include a combination of one or more CUs, one or more DUs, or one or more RUs. In some examples, a CU, a DU, or an RU may be implemented as a virtual unit, such as a virtual central unit (VCU), a virtual distributed unit (VDU), or a virtual radio unit (VRU), among other examples, which may be implemented as a virtual network function, such as in a cloud deployment (for example, an open cloud (O-Cloud) platform). An SMO framework may support RAN deployment and provisioning of non-virtualized and virtualized network elements.

In some examples, the wireless communication network 100 may be a heterogeneous network that includes network nodes 110 of various types. Different types of network nodes 110 may generally operate on the same or different operating bands, transmit at different power levels, or serve different coverage areas, each of which may be referred to as or associated with a particular cell 130 (for example, a cell 130a and a cell 130b).

The UEs 120 may be physically dispersed throughout the coverage area of the wireless communication network 100, and each UE 120 may be stationary or mobile. A UE 120 may be, may include, or also may be referred to as an access terminal, a mobile station, a client device, or a subscriber unit. A UE 120 may be, include, or be coupled with a cellular phone (for example, a smart phone), a personal digital assistant (PDA), a wireless modem, a wireless communication device, a handheld device, a laptop computer, a cordless phone, a wireless local loop (WLL) station, a tablet, a camera, a netbook, a smartbook, an ultrabook, a medical device, a biometric device, a wearable device (for example, a smart watch, smart clothing, smart glasses, a smart wristband, or smart jewelry), a gaming device, an entertainment device (for example, a music device, a video device, or a satellite radio), an XR device, a vehicular component or sensor, a smart meter or sensor, industrial manufacturing equipment, a Global Navigation Satellite System (GNSS) device (such as a Global Positioning System device or another type of positioning device), an artificially intelligent robot or other device implementing artificial intelligence, a UE function of a network node, or any other suitable device or function that may communicate in the wireless communication network 100.

Some UEs 120 may be classified according to different categories in association with different complexities or different capabilities. UEs 120 in a first category may be associated with relatively low complexity or cost such as NB-IoT devices or eMTC UEs. UEs 120 in a second category may include higher complexity or cost devices, such as mission-critical IoT devices, baseline UEs, high-tier UEs, advanced UEs, full-capability UEs, or premium UEs that are capable of URLLC, eMBB, or precise positioning in the wireless communication network 100. A third category of UEs 120 may have mid-tier complexity or capabilities (for example, capabilities between that of the UEs 120 of the first category and the UEs 120 of the second category). A UE 120 of the third category may be referred to as a reduced capability UE (“RedCap UE”), a mid-tier UE, an NR-Light UE, or an NR-Lite UE, among other examples.

In some examples, a network node 110 may be, may include, or may operate as an RU, a TRP, or a base station that communicates with one or more UEs 120 via a radio access link (which may be referred to as a “Uu” link). The radio access link may include a downlink and an uplink. “Downlink” (or “DL”) refers to a communication direction from a network node 110 to a UE 120, and “uplink” (or “UL”) refers to a communication direction from a UE 120 to a network node 110. Downlink and uplink resources may include time domain resources (for example, frames, subframes, slots, and symbols), frequency domain resources (for example, frequency bands, component carriers (CCs), subcarriers, resource blocks, and resource elements), and spatial domain resources (for example, particular transmit directions or beams).

Frequency domain resources may be subdivided into bandwidth parts (BWPs). A BWP may be a block of frequency domain resources (for example, a continuous set of resource blocks (RBs) within a full component carrier bandwidth) that may be configured at a UE-specific level. A UE 120 may be configured with both an uplink BWP and a downlink BWP (which may be the same or different). Each BWP may be associated with its own numerology (indicating a sub-carrier spacing (SCS) and cyclic prefix (CP)). A BWP may be dynamically configured or activated (for example, by a network node 110 transmitting a downlink control information (DCI) configuration to the one or more UEs 120) or reconfigured (for example, in real-time or near-real-time) according to changing network conditions in the wireless communication network 100 or specific requirements of one or more UEs 120. An active BWP defines the operating bandwidth of the UE 120 within the operating bandwidth of the serving cell.

As used herein, a downlink signal may be or include a reference signal, control information, or data. For example, downlink reference signals include a primary synchronization signal (PSS), a secondary SS (SSS), an SS block (SSB) (for example, that includes a PSS, an SSS, and a physical broadcast channel (PBCH)), a demodulation reference signal (DMRS), a phase tracking reference signal (PTRS), a tracking reference signal (TRS), and a channel state information (CSI) reference signal (CSI-RS), among other examples. A downlink signal carrying control information or data may be transmitted via a downlink channel. Downlink channels may include one or more control channels for transmitting control information and one or more data channels for transmitting data. Downlink reference signals may be transmitted in addition to, or multiplexed with, downlink control channel communications or downlink data channel communications. A downlink control channel may be specifically used to transmit DCI from a network node 110 to a UE 120. DCI generally contains the information the UE 120 needs to identify RBs in a subsequent subframe and how to decode them, including a modulation and coding scheme (MCS) or redundancy version parameters. Different DCI formats carry different information, such as scheduling information in the form of downlink or uplink grants, slot format indicators (SFIs), preemption indicators (PIs), transmit power control (TPC) commands, hybrid automatic repeat request (HARQ) information, new data indicators (NDIs), among other examples. A downlink data channel may be used to transmit downlink data (for example, user data associated with a UE 120) from a network node 110 to a UE 120. Downlink control channels may include physical downlink control channels (PDCCHs), and downlink data channels may include physical downlink shared channels (PDSCHs). Control information or data communications may be transmitted on a PDCCH and PDSCH, respectively. For example, a PDCCH can carry DCI, while a PDSCH can carry a MAC control element (MAC-CE), an RRC message, or user data, among other examples. Each PDSCH may carry one or more transport blocks (TBs) of data.

As used herein, an uplink signal may include a reference signal, control information, or data. For example, uplink reference signals include a sounding reference signal (SRS), a PTRS, and a DMRS, among other examples. An uplink signal carrying control information or data may be transmitted via an uplink channel. An uplink channel may include one or more control channels for transmitting control information and one or more data channels for transmitting data. Uplink reference signals may be transmitted in addition to, or multiplexed with, uplink control channel communications or uplink data channel communications. An uplink control channel may be specifically used to transmit uplink control information (UCI) from a UE 120 to a network node 110. An uplink data channel may be used to transmit uplink data (for example, user data associated with a UE 120) from a UE 120 to a network node 110. Uplink control channels may include physical uplink control channels (PUCCHs), and uplink data channels may include physical uplink shared channels (PUSCHs). Control information or data communications may be transmitted on a PUCCH and PUSCH, respectively. For example, a PUCCH can carry UCI, while a PUSCH can carry a MAC-CE, an RRC message, or user data, among other examples. UCI can include a scheduling request (SR), HARQ feedback information (for example, a HARQ acknowledgement (ACK) indication or a HARQ negative acknowledgement (NACK) indication), uplink power control information (for example, an uplink TPC parameter), or CSI, among other examples. CSI can include a channel quality indicator (CQI) (indicative of downlink channel conditions to facilitate selection of transmission parameters, such as an MCS, by a network node 110), a precoding matrix indicator (PMI), a CSI-RS resource indicator (CRI) (for example, indicative of a beam used to transmit a CSI-RS), an SS/PBCH resource block indicator (SSBRI) (for example, indicative of a beam used to transmit an SSB), a layer indicator (LI), a rank indicator (RI), or measurement information (for example, a layer 1 (L1)-reference signal received power (RSRP) parameter, a received signal strength indicator (RSSI) parameter, a reference signal received quality (RSRQ) parameter, among other examples) which can be used for beam management, among other examples. Each PUSCH may carry one or more TBs of data.

The information (for example, data, control information, or reference signal information) transmitted by a network node 110 to a UE 120, or vice versa, may be represented as a sequence of binary bits that are mapped (for example, modulated) to an analog signal waveform (for example, a discrete Fourier transform (DFT)-spread-orthogonal frequency division multiplexing (OFDM) (DFT-s-OFDM) waveform or a CP-OFDM waveform) that is transmitted by the network node 110 or UE 120 over a wireless communication channel. In some examples, the network node 110 or the UE 120 (for example, using the processing system 145 or the processing system 140, respectively) may select an MCS (for example, an order of quadrature amplitude modulation (QAM), such as 64-QAM, 128-QAM, or 256-QAM, among other examples) for a downlink signal or an uplink signal. For example, the network node 110 may select an MCS for a downlink signal in accordance with UCI received from the UE 120 or may transmit, to the UE 120, an indication of an MCS to be applied for an uplink signal.

A network node 110 or a UE 120 (such as by using the processing system 145 or the processing system 140, respectively, or one or more coupled modems) may perform signal processing on the information (such as filtering, amplification, modulation, digital-to-analog conversion, an IFFT operation, multiplexing, interleaving, mapping, or encoding, among other examples) to generate a processed signal in accordance with the selected MCS. In some examples, the network node 110 or the UE 120 (for example, using the processing system 145 or the processing system 140, respectively, or one or more coupled encoders or modems) may perform a channel coding operation or a forward error correction (FEC) operation to control errors in transmitted information. For example, the network node 110 or the UE 120 may perform an encoding operation to generate encoded information (such as by selectively introducing redundancy into the information, typically using an error correction code (ECC), such as a polar code or an LDPC code). The network node 110 or the UE 120 (for example, using the processing system 145 or one or more modems) may further perform spatial processing (for example, precoding) on the encoded information to generate one or more processed or precoded signals for downlink or uplink transmission, respectively. In some examples, the network node 110a or the UE 120a may perform codebook-based precoding or non-codebook-based precoding. Codebook-based precoding may involve selecting a precoder (for example, a precoding matrix) using a codebook. For example, the network node 110a may provide precoding information indicating which precoder, defined by the codebook, is to be used by the UE 120a. Non-codebook-based precoding may involve selecting or deriving a precoder based on, or otherwise associated with, one or more downlink or uplink signal measurements. The network node 110a or the UE 120a may transmit the processed downlink or uplink signals, respectively, via one or more antennas.

The network node 110a or the UE 120a may receive uplink signals or downlink signals, respectively, via one or more antennas. The network node 110a or the UE 120a (for example, using the processing system 145 or the processing system 140, respectively, or one or more coupled modems) may perform signal processing (for example, in accordance with the MCS) on the received uplink or downlink signals, respectively (such as filtering, amplification, demodulation, analog-to-digital conversion, an FFT operation, demultiplexing, deinterleaving, de-mapping, equalization, interference cancellation, or decoding, among other examples), to map the received signal(s) to a sequence of binary bits (for example, received information) that estimates the information transmitted by the network node 110 or the UE 120 via the downlink or uplink signals. The network node 110a or the UE 120a (for example, using the processing system 145 or the processing system 140, respectively, or a coupled decoder or one or more modems) may decode the received information (such as by using an ECC, a decoding operation, or an FEC operation) to detect errors or correct bit errors in the received information to generate decoded information. The decoded information may estimate the information transmitted via the downlink or uplink signals.

In some examples, a UE 120 and a network node 110 may perform MIMO communication. MIMO communication generally refers to transmitting or receiving multiple signals (such as multiple layers or multiple data streams) simultaneously over the same time and frequency resources. A network node 110 or a UE 120 may communicate using single-user MIMO or multi-user MIMO (MU-MIMO), the latter of which being used by a network node 110 to simultaneously transmit signals to multiple UEs 120. MIMO techniques may involve spatial multiplexing (multi-layer transmission) or beamforming. To implement beamforming, the amplitudes or phases of signals transmitted via antenna elements may be modulated and shifted relative to each other (such as by manipulating a phase shift, a phase offset, or an amplitude) to generate one or more beams. For example, a network node 110 may generate one or more beams 160a, and a UE 120 may generate one or more beams 160b. The term “beam” may refer to a directional transmission of a wireless signal toward a receiving device or otherwise in a desired direction, a directional reception of a wireless signal from a transmitting device or otherwise in a desired direction, a direction associated with such a directional transmission or directional reception, a set of directional resources associated with a signal transmission or signal reception (for example, an angle of arrival, a horizontal direction, or a vertical direction), or a set of parameters or resources associated with one or more aspects of a directional signal, among other examples.

In some examples, a network node 110 or a UE 120 may implement massive MIMO, which may be associated with an increased (for example, “massive”) quantity of antennas at the network node 110 or at the UE 120, such as in a network implementing mmWave technology, which enables more precise beamforming or reduced interference. In some examples, the wireless communication network 100 may implement multi-TRP (mTRP) operation (including redundant transmission or reception on multiple TRPs) or non-coherent joint transmission (NC-JT).

The network node 110 and the UE 120 may establish a communication link or beam pair, and otherwise increase reliability, throughput, signal strength, or other signal properties for MIMO communications, by performing beam management operations, such as an initial beam acquisition operation, a beam refinement operation, or a beam recovery operation. For example, an initial beam acquisition operation may involve the network node 110 transmitting signals (for example, SSBs or other signals) via respective beams (for example, of the beams 160 of the network node 110) and the UE 120 receiving and measuring the signal(s) via respective beams of multiple beams (for example, from the beams 160 of the UE 120) to identify a best beam (or beam pair) for communication between the UE 120 and the network node 110. A beam refinement operation may involve a first device (for example, the UE 120 or the network node 110) transmitting signal(s) via a subset of beams (for example, identified based on, or otherwise associated with, measurements reported as part of one or more other beam management operations). A second device (for example, the network node 110 or the UE 120) may receive the signal(s) via a single beam (for example, to identify the best beam for communication from the subset of beams). The beam(s) may be identified or defined via one or more spatial parameters, such as a transmission configuration indicator (TCI) state or a quasi co-location (QCL) parameter, among other examples.

Some aspects and techniques as described herein may be implemented, at least in part, using an artificial intelligence (AI) program (for example, referred to herein as an “AI/ML model”), such as a program that includes a machine learning (ML) model or an artificial neural network (ANN) model. The AI/ML model may be deployed at one or more devices 165 (for example, one or more network nodes 110, one or more UEs 120, one or more servers, or one or more components of a cloud computing network, among other examples). For example, in a deployment in which AI/ML functionality is performed independently at a device 165, sometimes referred to as “overlay AI/ML,” the AI/ML model (or an instance or portion of the AI/ML model) may be deployed at a UE 120 (for example, by the processing system 140), a network node 110 (for example, by the processing system 145), one or more servers, or one or more components of a cloud computing network, among other examples. Additionally, or alternatively, in a deployment where AI/ML functionality is coordinated between different devices 165, sometimes referred to as “coordinated AI/ML,” or performed at all device and network layers, sometimes referred to as “native AI/ML,” the AI/ML model (or an instance of the AI/ML model) may be deployed at multiple devices 165 (for example, a first portion of the AI/ML model may be deployed at a UE 120 and a second portion of the AI/ML model may be deployed at a network node 110). In other examples of coordinated AI/ML or native AI/ML, a first AI/ML model may be deployed at a UE 120 and a second AI/ML model may be deployed at a network node 110. The AI/ML model(s) may be configured to enhance various aspects of the wireless communication network 100 (for example, to increase privacy, reliability, or efficient use of network bandwidth, or to reduce latency, among other examples). For example, the AI/ML model(s) may be trained to identify patterns or relationships in data corresponding to the wireless communication network 100, a device, or an air interface, among other examples. The AI/ML model(s) may support operational decisions relating to one or more aspects associated with wireless communications devices, networks, or services.

Accordingly, in some examples, the AI/ML model(s) may enable AI-as-a-Service (for example, an end-to-end AI/ML service via a user plane) for use cases, such as a self-organizing network (SON), minimization of drive test (MDT), quality of experience (QoE), positioning, sensing, predictive mobility, or traffic prediction, among other examples. In some examples, AI-as-a-Service use cases may include measurement collection reporting by a UE 120, device selection criteria (for example, according to a geographical area where measurements are to be collected or UE capabilities to be used to collected measurements), or reporting configurations (for example, reporting parameters such as location, time, or sensor information, among other examples). Additionally, or alternatively, the AI/ML model(s) may enable AI/ML procedures (for example, RAN-triggered service establishment, configuration, inferencing using UE-side or network-side models, performance monitoring or management, or capability signaling, among other examples). Additionally, or alternatively, the AI/ML model(s) may enable RAN-based AI/ML services via one or more application program interfaces (APIs) or management interfaces for use cases, such as beam management, radio resource monitoring (RRM) relaxation, mobility prediction, load prediction, network energy savings, or coverage and capacity improvements, among other examples.

As shown in FIG. 1, a first wireless communication device (WCD) 170 may communicate with a second WCD 175. The first WCD 170 may be a network node 110, a UE 120, or another type of WCD. The second WCD 175 may be a network node 110, a UE 120, or another type of WCD. The first WCD 170 may include a processing system 180. The second WCD 175 may include a processing system 185. The processing system 180 and the processing system 185 may be similar to the processing system 140 and the processing system 145. The first WCD 170 may perform an encoding operation to generate encoded information (such as by selectively introducing redundancy into the information, typically using an ECC, such as an LDPC code). For example, the first WCD 170 may provide or transmit, and the second WCD 175 may obtain or receive, the encoded information. The second WCD 175 may decode (or perform a decoding operation) on the encoded information to obtain the information, such as by using the ECC, such as the LDPC code.

In some aspects, the first WCD 170 may include a communication manager 150. As described in more detail elsewhere herein, the communication manager 150 may encode a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field; and provide, to a second wireless communication device, the encoded communication. Additionally, or alternatively, the communication manager 150 may perform one or more other operations described herein.

In some aspects, the second WCD 175 may include a communication manager 155. As described in more detail elsewhere herein, the communication manager 155 may obtain an encoded communication; and decode the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field. Additionally, or alternatively, the communication manager 155 may perform one or more other operations described herein.

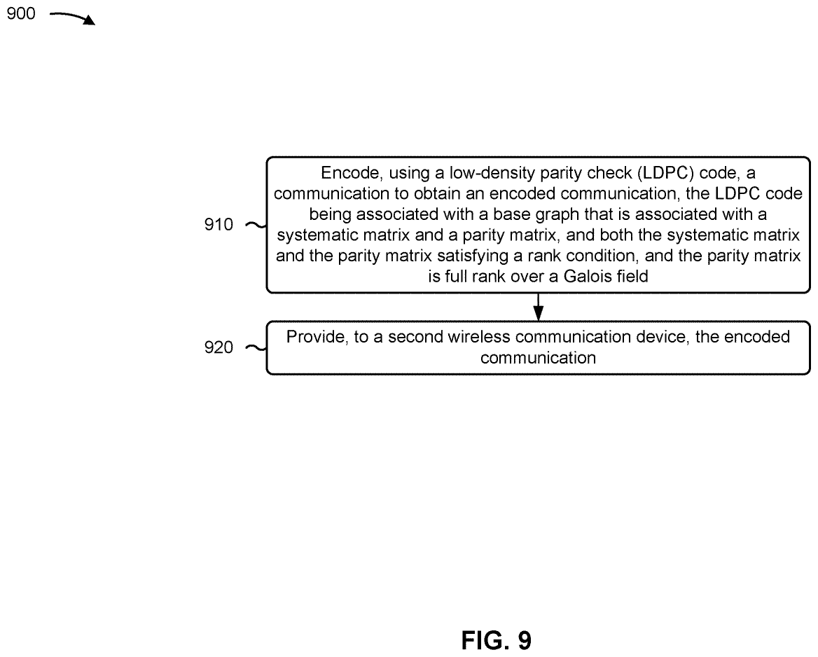

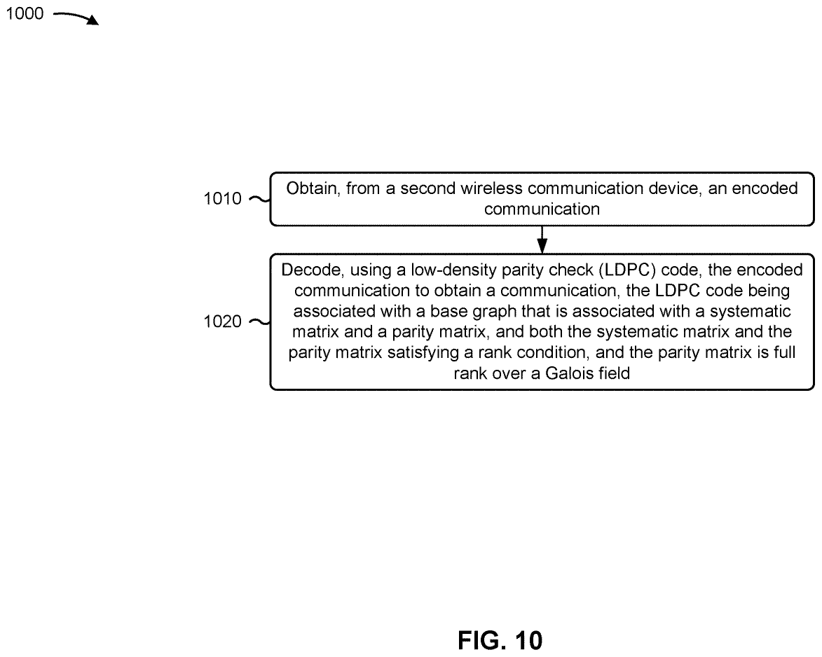

The network node 110, the processing system 145 of the network node 110, the UE 120, the processing system 140 of the UE 120, the processing system 180 of the WCD 170, the processing system 185 of the WCD 175, or any other component(s) of FIG. 1 may implement one or more techniques or perform one or more operations associated with rank condition for LDPC codes, as described in more detail elsewhere herein. For example, the processing system 145 of the network node 110, r the processing system 140 of the UE 120, the processing system 180 of the WCD 170, or the processing system 185 of the WCD 175 may perform or direct operations of, for example, process 900 of FIG. 9, process 1000 of FIG. 10, or other processes as described herein (alone or in conjunction with one or more other processors). In some aspects, the wireless communication device described herein is the network node 110, is included in the network node 110, or includes one or more components of the network node 110 shown in FIG. 1. In some other aspects, the wireless communication device described herein is the UE 120, is included in the UE 120, or includes one or more components of the UE 120 shown in FIG. 1. Memory of the network node 110 may store data and program code (or instructions) for the network node 110. In some examples, the memory of the network node 110 may store data relating to a UE 120, such as RRC state information or a UE context. Memory of a UE 120 may store data and program code (or instructions) for the UE 120, such as context information. In some examples, the memory of the UE 120 or the memory of the network node 110 may include a non-transitory computer-readable medium storing a set of instructions for wireless communication. For example, the set of instructions, when executed by one or more processors (for example, of the processing system 145, the processing system 140, the processing system 180, or the processing system 185) of the network node 110, or the UE 120, may cause the one or more processors to perform process 900 of FIG. 9, process 1000 of FIG. 10, or other processes as described herein. In some examples, executing instructions may include running the instructions, converting the instructions, compiling the instructions, or interpreting the instructions, among other examples.

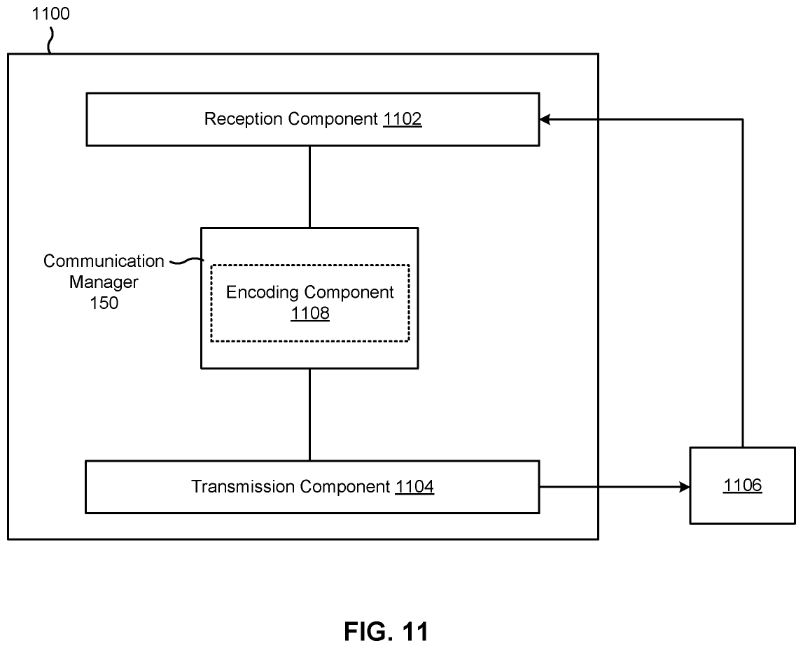

In some aspects, the first WCD 170 includes means for encoding, using an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field; or means for providing, to a second wireless communication device, the encoded communication. In some aspects, the means for the first WCD 170 to perform operations described herein may include, for example, one or more of communication manager 150, processing system 180, a radio, one or more RF chains, one or more transceivers, one or more antennas, one or more modems, a reception component (for example, reception component 1102 depicted and described in connection with FIG. 11), or a transmission component (for example, transmission component 1104 depicted and described in connection with FIG. 11), among other examples.

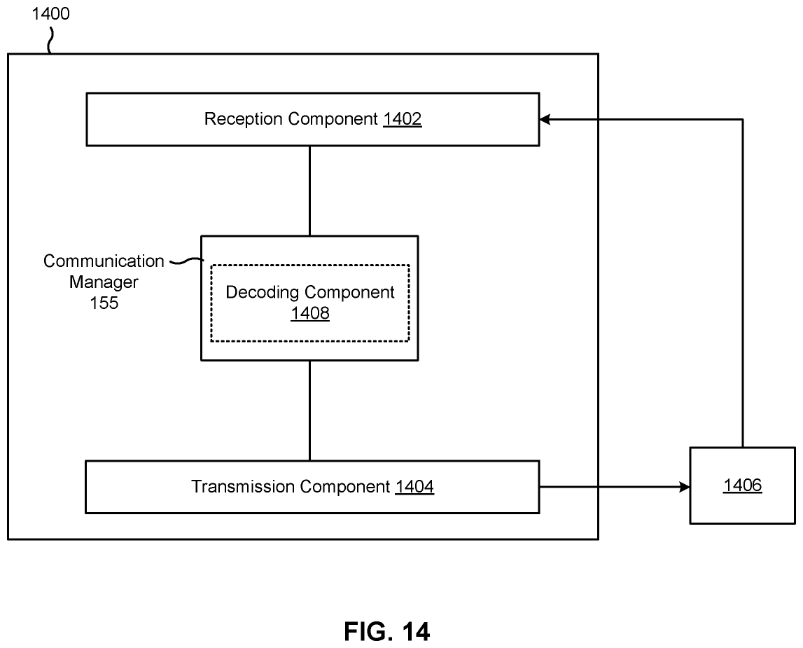

In some aspects, the second WCD 175 includes means for obtaining, from a second wireless communication device, an encoded communication; or means for decoding, using a LDPC code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field. In some aspects, the means for the second WCD 175 to perform operations described herein may include, for example, one or more of communication manager 155, processing system 185, a radio, one or more RF chains, one or more transceivers, one or more antennas, one or more modems, a reception component (for example, reception component 1402 depicted and described in connection with FIG. 14), or a transmission component (for example, transmission component 1404 depicted and described in connection with FIG. 14), among other examples.

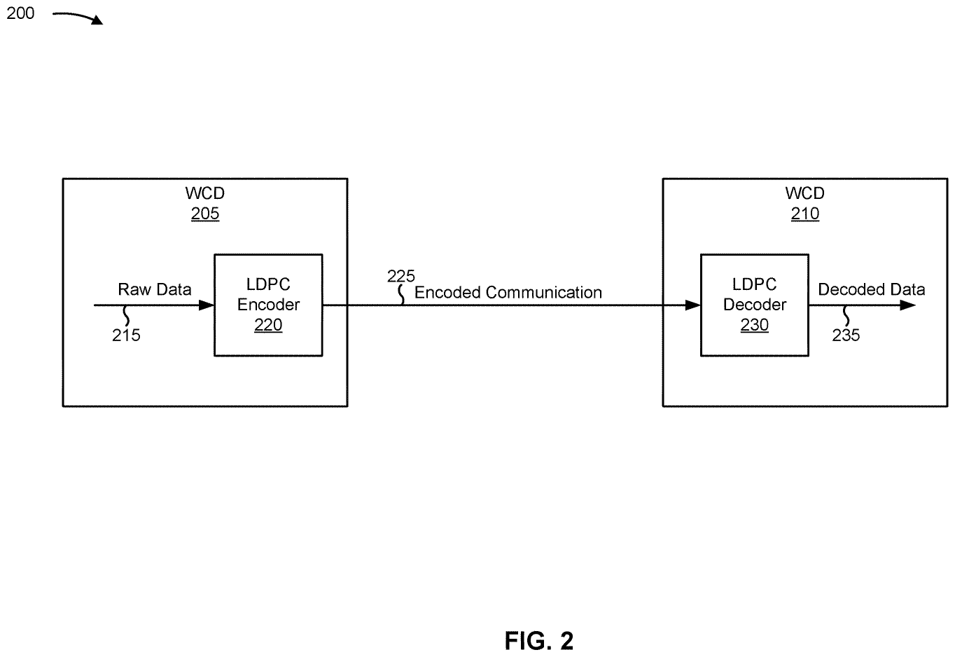

FIG. 2 is a diagram illustrating an example 200 of communication using LDPC codes. As shown in FIG. 2, example 200 includes communication between a first WCD, shown in FIG. 2 and referred to herein as WCD 205, and a second WCD, shown in FIG. 2 and referred to herein as WCD 210. The WCD 205 may be a network node 110, a UE 120, or the WCD 170. The WCD 210 may be a network node 110, a UE 120, or the WCD 175. As shown in FIG. 2, the WCD 205 includes an LDPC encoder 220 and the WCD 210 includes an LDPC decoder 230, which the WCD 205 and the WCD 210 may use to implement an LDPC channel coding scheme in which LDPC codes are used for one or more data channel transmissions. For example, in some aspects, the WCD 205 may correspond to a network node 110 and the WCD 210 may correspond to a UE 120, and the LDPC channel coding scheme may be used for one or more PDSCH transmissions from the network node 110 to the UE 120. Additionally, or alternatively, the WCD 205 may correspond to a UE 120 and the WCD 210 may correspond to a network node 110, and the LDPC channel coding scheme may be used for one or more PUSCH transmissions from the UE 120 to the network node 110. Additionally, or alternatively, the WCD 205 may correspond to a first UE 120 and the WCD 210 may correspond to a second UE 120, and the LDPC channel coding scheme may be used for one or more physical sidelink shared channel (PSSCH) transmissions from the first UE 120 to the second UE 120. In some aspects, the WCD 205 and the WCD 210 may communicate in a wireless network, such as the wireless communication network 200.

In some aspects, a communication from the WCD 205 to the WCD 210 may be encoded based at least in part on an error correcting code (sometimes referred to as an error correcting scheme), such that the WCD 210 can determine whether the communication was properly transmitted (e.g., to verify that the communication was not corrupted by noise or the like) or so that the WCD 210 can correct any transmission errors using redundant bits provided by the error correcting code. One example of an error correcting code is an LDPC code. A communication may be encoded according to an LDPC channel coding scheme to provide for error detection at the WCD 210. Encoding for an LDPC code may be performed based at least in part on a base graph (e.g., a sparse bipartite graph) that may identify a codeword to be generated from an input data set or information to append to an input data set to form the LDPC code.

More particularly, as shown in FIG. 2, the WCD 205 may be in wireless communication with the WCD 210. When the WCD 205 transmits data to the WCD 210, the WCD 205 may first encode the data using an error correcting code, such as an LDPC code. For example, as shown in FIG. 2, the WCD 205 may process raw data 215 (e.g., information bits) to be transmitted to the WCD 210 by feeding the raw data 215 through the LDPC encoder 220, among other signal processing components. The WCD 205 may perform other signal processing operations (e.g., interleaving or the like), which are not shown in FIG. 2. The LDPC encoder 220 may add error correction bits (e.g., parity bits) to the raw data 215 based at least in part on a selected base graph or based at least in part on a target code rate, forming an encoded data stream 225. In some examples, the target code rate may be expressed as R=k/n, where R is the target code rate, k is a number of information bits in the raw data 215 input to the LDPC encoder 220, and n is a total number of bits in the encoded data stream transmitted to the WCD 210 (e.g., the target code rate is the proportion of the encoded data stream 225 that is useful, or non-redundant). For example, LDPC codes associated with a lower code rate provide more error protection, but may incur more overhead, relative to LDPC codes with a higher code rate.

As further shown in FIG. 2, the WCD 205 may transmit the encoded data stream 225 to the WCD 210 over a wireless link (e.g., a wireless access link for uplink or downlink communication, or a wireless sidelink for sidelink communication), where the encoded data stream 225 is fed through the LDPC decoder 230 (and, in some examples, other signal processing components such as a de-interleaver, among other examples) in order to recover the information bits from decoded data 235 output from the LDPC decoder 230. For example, the LDPC decoder 230 may use an iterative belief propagation decoding scheme (also known as a message passing decoding scheme) to decode the encoded data stream 225.

As indicated above, FIG. 2 is provided as an example. Other examples may differ from what is described with regard to FIG. 2.

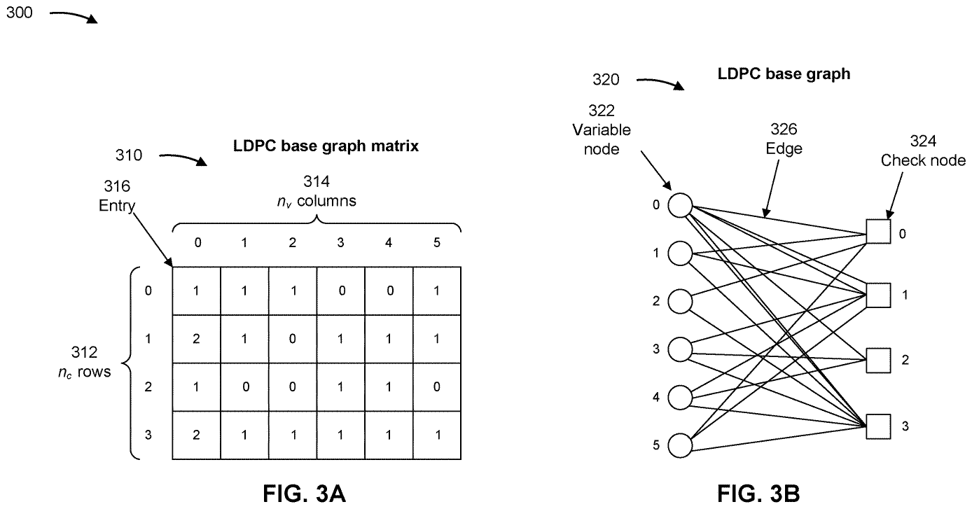

FIGS. 3A and 3B are diagrams illustrating an example 300 of an LDPC base graph matrix 310 and an LDPC base graph 320. As described herein, the LDPC base graph matrix 310 and the LDPC base graph 320 may be used to encode an LDPC code, which is a linear block code that can provide error correction capabilities that may be close to channel capacity. For example, the LDPC base graph matrix 310 and the LDPC base graph 320 may be used by the LDPC encoder 220 of the WCD 205 to encode the raw data 215 (e.g., to generate the encoded data stream 225). In some examples, an LDPC code may be represented according to a base graph (for example, a sparse bipartite graph) that may identify a codeword to be generated from an input data set or information to append to an input data set to form the LDPC code. For example, a bipartite graph may include variable nodes representing information bits (also known as message bits or systematic bits) and check nodes representing parity-check equations. The edges between the variable nodes and the check nodes may define how the information bits are related through the parity-check equations, which may be solved using the input data set to determine the values of the parity bits. For example, the original information bits may be combined with the parity bits to form an LDPC code containing the input data (information bits) and the error-correcting (parity) bits.

As shown in FIG. 3A, the LDPC base graph matrix 310 has a size n_{c}×nᵥ including a total number of n_{c} rows 312 and a total number of nᵥ columns 314. Additionally, both n_{c} and nᵥ are positive integers, and the total number of rows n_{c} may be smaller than the total number of columns nᵥ. Each entry 316 of the LDPC base graph matrix 310 is a non-negative integer in a set of integers ranging from 0 to a bounded integer that is independent of the size of the LDPC base graph matrix 310. For example, the set of integers may be {0,1}, {0,1,2}, or {0,1,2, . . . , dₘₐₓ} for some dₘₐₓ integer. Additionally, each row 312 of the LDPC base graph matrix 310 may be indexed by a respective integer from 0 to n_{c}−1. Each column 314 of the LDPC base matrix 310 may be indexed by a respective integer from 0 to nᵥ−1.

As further shown in FIG. 3B, the LDPC base graph matrix 310 is associated with an LDPC base graph 320 that represents the LDPC base matrix 310. In some examples, the LDPC base graph 320 may be a bipartite graph including a set of variable nodes 322, a set of check nodes 324, and a set of edges 326 connecting the set of variable nodes 322 and the set of check nodes 324. For example, each variable node 322 may be labelled by a respective integer from 0 to nᵥ−1, such that each variable node 322 corresponds to a column 314 of the LDPC base matrix 310. Furthermore, each check node 324 may be labelled by a respective integer from 0 to n_{c}−1, such that each check node 324 corresponds to a row 312 of the LDPC base matrix 310. Additionally, an edge 326 exists between a variable node i and a check node a if a value of the entry at (column a, row i) of the LDPC base graph matrix 310 is non-zero, and the number of edges between the variable node i and the check node a is equal to the value of the entry at (column a, row i) in the LDPC base graph matrix 310. For example, the entry at (column 0, row 0) of the LDPC base graph matrix 310 has a value of 1, which is represented in the edge 326 between variable node 0 and check node 0. In some examples, multiple edges 326 exist between a variable node i and a check node a if a value of the entry at (column a, row i) of the LDPC base graph matrix 310 is greater than one. Furthermore, a variable node 322 is a state node if a corresponding column 314 of the LDPC base graph matrix 310 is a state column. In addition, a state variable or state column may refer to a variable node of an LDPC code associated with a non-transmitted (e.g., punctured) set of information bits.

As indicated above, FIGS. 3A and 3B are provided as examples. Other examples may differ from what is described with regard to FIGS. 3A and 3B.

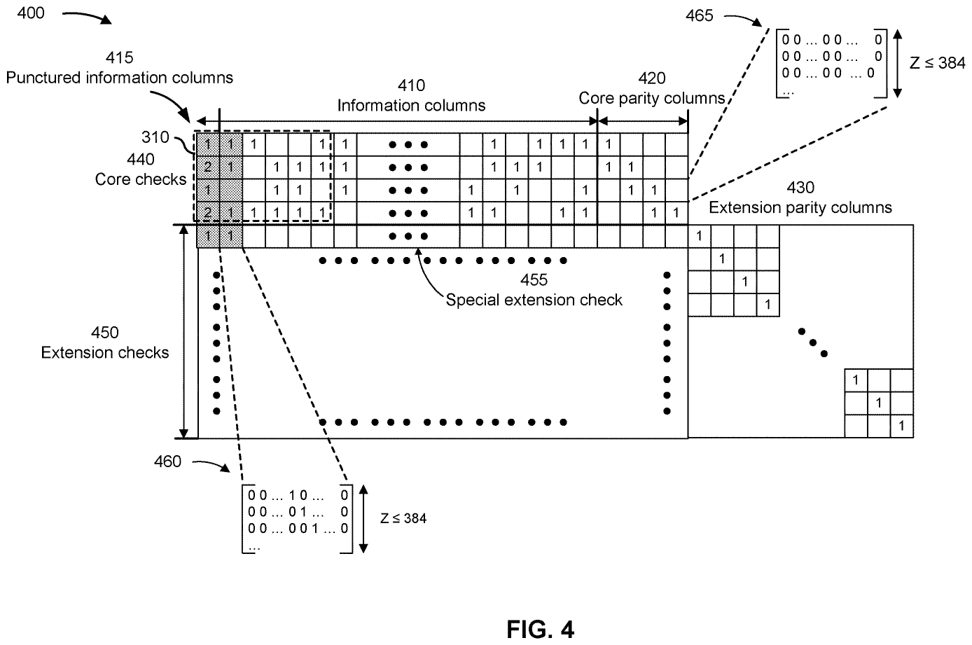

FIG. 4 is a diagram illustrating an example of a PCM 400 associated with an LDPC code. As described herein, the PCM shown in FIG. 4 may be used for a QC-LDPC code, where the PCM 400 has a compact representation that may enable efficient LDPC encoding and high parallelism in a corresponding LDPC decoder architecture. In some examples, the PCM shown in FIG. 4 may be used by the WCD 205 to encode the raw data 215 via the LDPC encoder 220. Similarly, the PCM shown in FIG. 4 may be used by the WCD 210 to decode the encoded data stream 225 via the LDPC decoder 230. As shown in FIG. 4, the LDPC base graph matrix 310 may be a portion of the PCM 400.

For example, the PCM 400 is a set of codewords that satisfy one or more parity check conditions, which may be defined according to a base graph and lifting values (also known as a protograph LDPC code). In particular, as described herein, the base graph (or protograph) is a small graph that captures macroscopic properties associated with the QC-LDPC code, such as a decoding threshold. After the base graph has been constructed, a lifting procedure is applied in which the base graph is copied multiple times and connections between different copies of the base graph are permuted to construct one larger graph. Otherwise, without permuting the different copies of the base graph into one larger graph, there would be K small graphs that are not connected to each other, which may result in no coding gain. The copying and permutation is a cyclic permutation along edges of the base graph, and is generally known as cyclic shift lifting. Accordingly, the LDPC code resulting from the encoding procedure of constructing the base graph and applying the lifting procedure is known as a quasi-cyclic LDPC code.

In some examples, the base graph associated with an LDPC code (such as the LDPC base graph 320) may be described or represented as a matrix (or base graph matrix), such as the PCM 400 shown in FIG. 4. For example, as shown in FIG. 4, the PCM includes a set of information columns 410, a set of core parity columns 420, and a set of extension parity columns 430, which represent variable nodes associated with the PCM. In addition, the PCM includes a set of core check rows 440 and a set of extension check rows 450, which represent check nodes associated with the PCM. The extension check rows 450 include a special extension check 455, and the information columns include one or more punctured information columns 415. For each entry in the PCM, the value is a non-negative integer representing the number of connections between the variable node and the check node corresponding to the entry (e.g., a 0 means that there is no connection between the corresponding variable node and check node, a 1 means that there is 1 edge connecting the corresponding variable node and check node, a 2 means that there are 2 edges connecting the corresponding variable node and check node, and so on). As described herein, each variable node has a degree that denotes the number of check nodes that the variable node is connected to in the base graph (e.g., the number of rows with a positive value), where a degree-n variable node is connected to n check nodes. The extension check rows 450 include a special extension check 455, and the information columns include one or more punctured information columns 415.

As further shown in FIG. 4, and by reference number 460, each entry that has a positive value (e.g., one) may be replaced by a permuted identity matrix that indicates the number of cyclic permutations applied to each edge in the base graph. The lifting values may be integers in a range between 0 and Z, where Z is a lift value (e.g., the number of copies that are applied to the base graph). Accordingly, after constructing the base graph and applying the lifting procedure, the resulting QC-LDPC code has a block length equal to the size of the base graph multiplied by the lifting factor. As shown by reference number 465, each entry that has a value of zero may be replaced by a Z×Z matrix having all entries with a value of zero.

As indicated above, FIG. 4 is provided as an example. Other examples may differ from what is described with regard to FIG. 4.

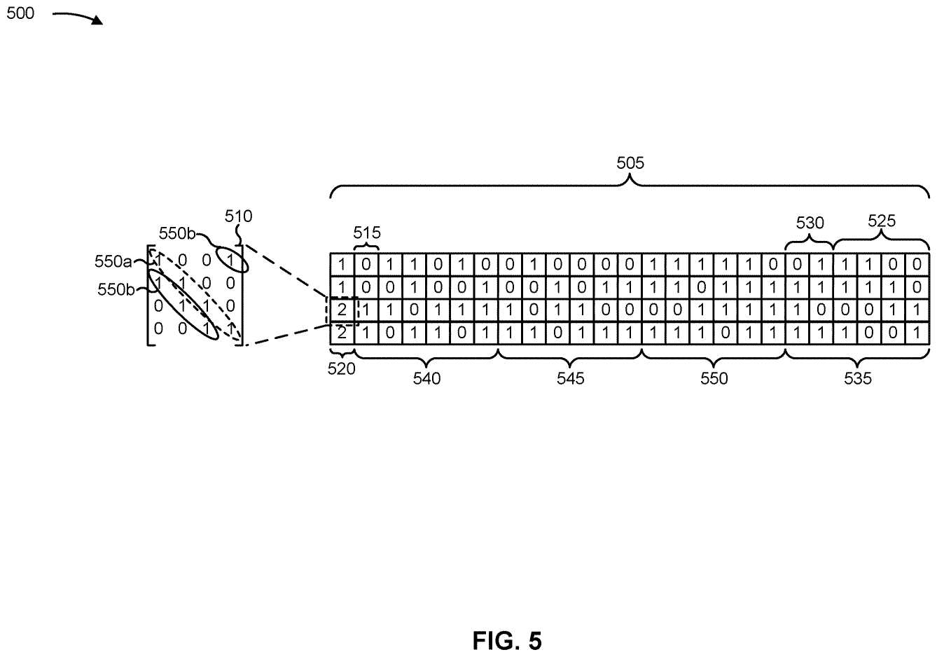

FIG. 5 is a diagram illustrating an example 500 of a base graph 505 that supports fast converging LDPC techniques. For example, transmissions between two WCDs, such as the WCD 170 and the WCD 175, may be encoded according to an LDPC code. In such examples, a transmitting device may transmit a signal including one or more coded bits to a receiving device based on encoding the signal. The receiving device may decode the signal based on receiving the signal and generating an LDPC code associated with the signal.

The transmitting device may generate the LDPC code based on a base graph 505. The transmitting device or the receiving device, or both, may perform lifting on the base graph 505 according to a lifting matrix 510, which may be an example of a dual-diagonal lifting matrix. The base graph 505 may include one or more variable nodes 515. The base graph 505 may include a punctured variable node 520, which may be in a first node position. In some examples, the punctured variable node 520 may be an example of a punctured variable node having double-edged or multi-edged elements. The base graph 505 may include a set of parity nodes 525 and a set of unshaped bits 530 (e.g., unshaped systematic bits). The set of unshaped bits 530 may be at the beginning of the set of information nodes of the base graph 505 or at the end of the set of information nodes of the base graph 505. In some examples, the portion of the base graph 505 shown in FIG. 5 may be an example of a core of the base graph 505.

In some examples, each of the one or more variable nodes 515 may be associated with a degree. In such examples, a numerical value associated with each degree may indicate that each of the one or more variable nodes 515 is associated with a quantity of check nodes similar to (e.g., equal to) the numerical value associated with each degree. For example, one or more variable nodes 515 of the base graph 505 may be associated with two check nodes (e.g., second degree nodes), and one or more variable nodes 515 of the base graph 505 may be associated with three check nodes (e.g., third degree nodes). In an example, the punctured variable node 520 may have a degree of six based on having two double-edged elements and two single-edged elements.

The base graph 505 may include a single punctured node (e.g., the punctured variable node 520), which may provide faster convergence compared to base graphs with two punctured nodes. The single punctured node may have double-edge or multi-edge elements in the base graph, which may improve asymptotic performance. For example, the total degree of punctured nodes may be increased by supporting multiple edges to a same check node. The base graph 505 may converge faster than other base graphs (e.g., based graphs with a single punctured node) and may match asymptotically. In some examples, the base graph 505 may have a larger core size than some other base graphs. The rate of the core may be greater than or equal to the rate of the core of some other systems. For example, the rate of the core of the base graph 505 may be greater than or equal to 0.88 (e.g., for high throughput scenarios).

The punctured nodes may provide threshold improvement. For example, the punctured node may increase the check node degree of the transmitted graph. The double edge structure may provide faster convergence and improved asymptotic performance. In some examples, the base graph 505 may support using an encoding chain of degree two and a HARQ extension of degree one. In some examples, the set of parity nodes 525 may have an accumulative chain structure which may be similar to some other base graphs (e.g., BG1).

In some examples, the base graph 505 may be implemented by a device by converting a double-edge graph into a single-edge format. For example, the device may use or introduce a virtual punctured node corresponding to a special check or special layer. A decoding device may use a decoding schedule where the decoding device revisits the special layer after every layer involving the double edge. For example, the virtual punctured layer may sore a separate copy of a log likelihood ratio. A parity check may equate the punctured node and the virtual node. For example, a device may effectively add a virtual row (e.g., a virtual check node) and a virtual column (e.g., a virtual variable node) to the base graph, such that a second edge between the punctured variable node is effectively moved to the virtual variable node.

The transmitting device or the receiving device, or both, may perform lifting on both edges of an entry of the punctured variable node 520 with two edges. For example, the entry of the punctured variable node 520 with two edges may be replaced by a summation of two circularly shifted identity matrices. A first identity matrix may have a first circular shift value 550-a, and a second identity matrix may have a second circular shift value 550-b. In the example shown by FIG. 5, the first circular shift value 550-a may be zero (e.g., the identity matrix is not circularly shifted), and the second circular shift value 550-b may be three. The lifting matrix 510 for the double-edge entry of the punctured variable node 520 may correspond to a summation of the two identity matrices with the respective circular shift values.

For the lifting procedure, each value of 1 in the base graph 505 may be replaced by a circularly shifted identity matrix. The circular shift values may be configured at the transmitting device, receiving device, or preconfigured for a wireless communications system including the transmitting device and receiving device. For each liftting size value (e.g., Z value), the lift values (e.g., or circular shift values) may be stored by a lift value matrix. For example, a 0 in the base graph 505 (e.g., no edge) may correspond to a −1 in the lift value matrix. A non-zero value (e.g., 1 or 2) in the base graph 505 may correspond to a lifting value in the lift value matrix. To specify lift values for double edges, the lift value matrix may indicate two lifting values for double edges in the base graph 505. In a first example, the lift value matrix may indicate two values, A and B. For example, the entry in the lift value matrix that corresponds to a double edge may store both A and B, or two separate lift values or circular shift values for the double edge. In another example, the entry in the lift value matrix that corresponds to the double edge may store a single value that is indicative of both lift values. For example, the entry may store a value that is based on the first lift value, the second lift value, and a lift size. For example, the entry in the lift value matrix may correspond to A+10*Z*B. In an example, for a lifting size value of Z=384, a first lifting value A of 181, and a second lifting value B of 186, the entry in the lifting value matrix may be 714421.

In the example shown by FIG. 5, the Z value or lifting size value for the base graph may be four. For example, the dimensions of the lifting matrix 510 may be Z×Z, or four columns with four rows. The Z value for FIG. 5 is exemplary, and other Z values may be used for a lifting size. In some examples, the lift size may be less than or equal to 384. In some implementations, the lift size may be configured to be larger than a threshold, which may prevent short cycles in an LDPC code. In some examples, Z value may be restricted or configured to be larger than a threshold size.

In some examples, the core of the base graph 505 may have a higher occurrence or density of double edges than an extension portion of the base graph 505. An example of the extension portion may be the extension checks 450 depicted and described in connection with FIG. 4. In some examples, the extension portion of the base graph 505 may refer to lower check nodes, or check nodes five and beyond. The extension may have more single edges for faster convergence. For example, a majority of layers of the punctured node in the extension portion may have single edges.

In some examples, the transmitting device may map the elements of the base graph 505 (e.g., one or more parity bits and one or more unshaped bits of the coded bit) to different bits of a modulation constellation. For example, a first set of variable nodes may correspond to a first most significant bit (MSB) 540, a second set of variable nodes may correspond to a second MSB 545, a third set of variable nodes may correspond to a third MSB 550, and a fourth set of variable nodes may correspond to the least significant bit (LSB) 535.

A receiving device may receive a signal including information bits and parity bits according to the LDPC code. In some examples, the receiving device may generate the LDPC code according to a lifted graph. The lifted graph may include multiple connected copies of the base graph that are connected via edge permutation based on a lifting procedure. The receiving device may attempt to decode the information bits based on the parity bits, information nodes, and parity nodes. In some examples, the receiving device may perform layered decoding to decode the information bits. For example, the receiving device may decode single edge layers first then decode double edge layers. For example, the receiving device may decode the first and second layers (e.g., rows) of the base graph 505, then the receiving device may decode the third and fourth layers of the base graph 505. In some examples, the receiving device may start decoding from a lowest degree layer and finish decoding with a highest degree layer. In some examples, the receiving device may not connect a variable node to the parity checks that are decoded consecutively in the layered decoding. For example, a message update may not be ready based on a pipeline of the bits or the implementation. In some examples, asymmetric degree distribution for parity check nodes may assist layered decoding. In some examples, the base graph 505 may support degree one extension structure to assist decoding operations at the receiving device.

As indicated above, FIG. 5 is provided as an example. Other examples may differ from what is described with regard to FIG. 5.

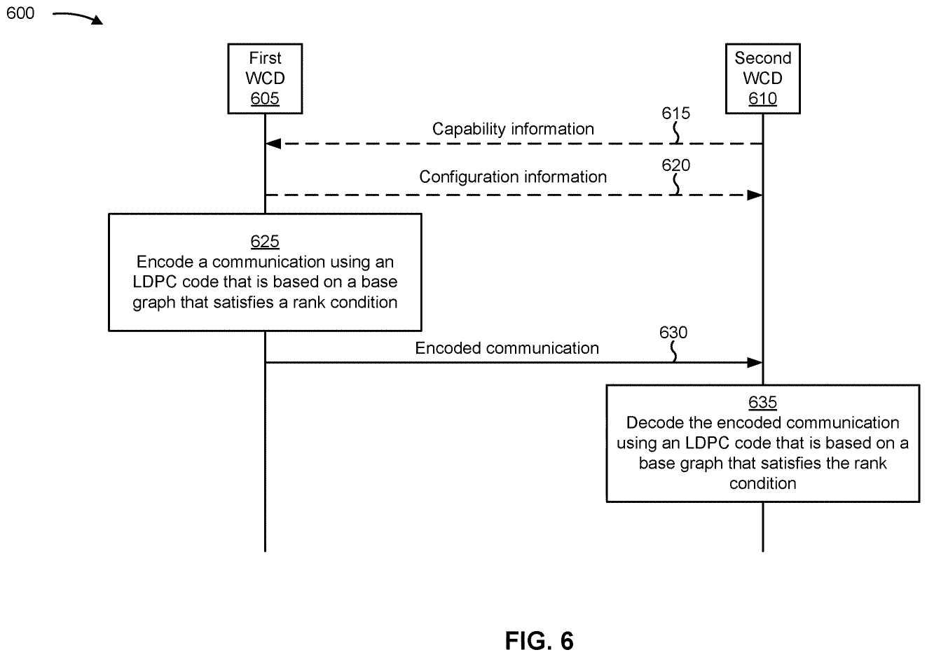

FIG. 6 is a diagram illustrating an example 600 associated with a rank condition for LDPC codes. As shown in FIG. 6, a first WCD 605 (e.g., a network node 110, a UE 120, or the WCD 170) may communicate with a second WCD 610 (e.g., a network node 110, a UE 120, or the WCD 175). In some aspects, the first WCD 605 and the second WCD 610 may be part of a wireless network (e.g., the wireless communication network 100). The first WCD 605 and the second WCD 610 may have established a wireless connection prior to operations shown in FIG. 6.

In some aspects, as shown by reference number 615, the first WCD 605 or the second WCD 610 (e.g., shown as the second WCD 610 in FIG. 6) may transmit capability information. The capability information may be included in a capability report. In an example where the second WCD 610 is a UE 120, the second WCD 610 may transmit the capability information via an uplink communication, a sidelink communication, a unicast communication, a broadcast communication, a UE assistance information (UAI) communication, a UCI communication, a sidelink control information (SCI) communication, a MAC-CE communication, an RRC communication, a PUCCH, a PUSCH, a physical sidelink control channel (PSCCH), or a PSSCH, among other examples. The capability information may indicate one or more parameters associated with respective capabilities of the second WCD 610. The one or more parameters may be indicated via respective information elements (IEs) included in a capability report. In some aspects, the first WCD 605 may transmit the capability information in addition to, or instead of, the second WCD 610.

The capability information may indicate whether the second WCD 610 supports a feature or one or more parameters related to the feature. For example, the capability information may indicate a capability or parameter for one or more base graphs or base graph matrices. As another example, the capability information may indicate a capability or parameter for using LDPC codes that are based on (or generated using) a base graph that satisfies a rank condition, as described herein. One or more operations described herein may be based on capability information. For example, the second WCD 610 may perform a communication in accordance with the capability information, or may receive configuration information that is in accordance with the capability information.

In some aspects, as shown by reference number 620, the first WCD 605 may transmit, and the second WCD 610 may receive, configuration information. In other aspects, the second WCD 610 may transmit, and the first WCD 605 may receive, the configuration information. In some aspects, the first WCD 605 or the second WCD 610 may receive the configuration information via one or more of system information signaling (e.g., a master information block (MIB) or a system information block (SIB), among other examples), RRC signaling, MAC signaling (e.g., one or more MAC-CEs), or physical layer signaling (e.g., DCI), among other examples.

In some aspects, the configuration information may indicate one or more candidate configurations or communication parameters. In some aspects, the one or more candidate configurations or communication parameters may be selected, activated, or deactivated by a subsequent indication. For example, the subsequent indication may select a candidate configuration or communication parameter from the one or more candidate configurations or communication parameters. In some aspects, the subsequent indication may include a dynamic indication, such as one or more MAC-CEs or one or more DCI messages, among other examples.

In some aspects, the configuration information may include an indication of a selection of one or more configuration parameters (e.g., a selection of the one or more configuration parameters already known to the first WCD 605 or the second WCD 610 or previously indicated by the network node or other network device), or explicit configuration information for the first WCD 605 or the second WCD 610 to use to configure the first WCD 605 or the second WCD 610, among other examples.

In some examples, the configuration information may not be expressly signaled to the first WCD 605 or the second WCD 610. For example, in some aspects, the configuration information may at least partially be defined by a wireless communication standard, such as the 3GPP. In such examples, the first WCD 605 (or another WCD) may not explicitly indicate such configuration information to the second WCD 610. For example, the first WCD 605 or the second WCD 610 may optionally obtain at least a portion of the configuration information from a configuration stored by the first WCD 605 or the second WCD 610 (e.g., an original equipment manufacturer (OEM) configuration). In some aspects, the configuration information may include a parameter or index that is indicative of information defined, or otherwise fixed, by a wireless communication standard, such as the 3GPP (e.g., rather than explicitly indicating the information).

In some aspects, the configuration information may indicate that the first WCD 605 or the second WCD 610 are to perform a channel coding operation. For example, the configuration information may indicate that the first WCD 605 is to encode communications using an LDPC code. The configuration information may indicate that the second WCD 610 is to decode communications using the LDPC code.

In some aspects, the configuration information may indicate one or more base graphs (or base graph matrices) to be used to generate the LDPC code. The one or more base graphs may be similar to the LDPC base graph 320, the PCM depicted in FIG. 4, or the base graph 505, among other examples. In some aspects, the one or more base graphs may include a base graph that includes a single punctured node. In some aspects, the single punctured node may include one or more parallel edges (e.g., an entry in the column, of the base graph matrix, corresponding to the single punctured node may include one or more entries with a value greater than one).

In some aspects, the configuration information may indicate that any base graph to be used for the LDPC code is to satisfy a rank condition. The rank condition may be associated with one or more submatrices included in the base graph. For example, the base graph may include a systematic matrix and a parity matrix. The configuration information may indicate that both the systematic matrix and the parity matrix are to satisfy the rank condition. For example, the rank condition may be based on, or otherwise associated with, one or more ranks of the one or more submatrices included in the base graph. For example, the rank condition may be based on, or otherwise associated with, a rank of the systematic matrix and a rank of the parity matrix. In some aspects, the rank condition being satisfied may include: a binary version of the systematic matrix being full rank over the Galois field of order two; and a binary version of the parity matrix being full rank over the Galois field of order two.

By the first WCD 605 and the second WCD 610 encoding or decoding communications using a base graph that satisfies the rank conditions, the described techniques may ensure that a PCM for the LDPC code is full rank over the Galois field of two regardless of a lifting operation that is used to generate the PCM. By ensuring that the PCM is full rank as a result of the base graph satisfying the rank condition, the described techniques may reduce the risk of the first WCD 605 mapping different sets of information bits to the same codeword. This reduces the risk of decoding errors of the LDPC code at the second wireless communication device that would have otherwise been caused by the first WCD 605 mapping different sets of information bits to the same codeword as a result of using a PCM that is not full rank.

The first WCD 605 or the second WCD 610 may be configured based at least in part on the configuration information. In some aspects, the first WCD 605 or the second WCD 610 may be configured to perform one or more operations described herein based at least in part on the configuration information.

As shown by reference number 625, the first WCD 605 may encode a communication. The first WCD 605 may encode the communication using an LDPC code. The LDPC code may be based on, or generated using, a base graph that satisfies the rank condition. This may ensure that the PCM, or lifted graph, of the LDPC code is full rank over the Galois field of order two, thereby reducing the likelihood of decoding errors that may be caused by the LDPC code producing two or more codewords that are mapped to the same coded bits. The communication may include one or more information bits. For example, the first WCD 605 may obtain the one or more information bits, such as from an application layer or a transport layer in a protocol stack associated with the first WCD 605.

To generate the LDPC code, the first WCD 605 may use the base graph, which is a small graph capturing the macroscopic properties of the code. The base graph may be represented as a matrix with entries that denote the quantity of edges between the corresponding variable nodes (columns in the matrix) and check nodes (rows in the matrix). The first WCD 605 may perform a lifting operation using base graph, where each entry in the base graph matrix is replaced by a circulant identity matrix of dimension Z×Z, where Z is the lift value. The lifting operation may result in a larger, lifted graph that maintains the degree distribution of the base graph while expanding the size of the base graph to accommodate a desired block length. In some examples, the base graph may include a single punctured node that is associated with one or more parallel edges or multiple edges. This reduces the convergence time for the decoding operation, such as the decoding operation described in connection with reference number 635.

Once the lifted graph is generated, the first WCD 605 may use the lifted graph (or PCM) to encode the information bits of the communication. The encoding process may include the first WCD 605 mapping the information bits to the variable nodes in the lifted graph and performing a series of linear operations to generate a set of parity bits. The first WCD 605 may determine or compute the set of parity bits based on the connections (e.g., edges) defined by the lifted graph, ensuring that the resulting codeword satisfies the parity-check equations defined by the lifted graph. The encoding operation may result in an encoded communication. The encoded communication may include the information bits and the set of parity bits generated using the LDPC code. The systematic nature of the LDPC code means that the encoded communication consists of the original information bits followed by the set of parity bits. The encoding operation may improve reliability for the communication by providing an encoded communication with error-correcting capabilities enabled by the LDPC code.

As described above, the base graph that is used to generate the lifted graph (or PCM) for the LDPC code may satisfy the rank condition. For example, the base graph may be associated with a systematic matrix and a parity matrix. The base graph may be associated with the systematic matrix and the parity matrix in that the base graph may be represented by a base graph matrix that includes the systematic matrix and the parity matrix. For example, the base may be represented as a matrix, where the columns correspond to variable nodes (representing the information and parity bits) and the rows correspond to check nodes (representing the parity-check equations). The base graph, B, may be represented as B=[BₛBₚ], where Bₛ is the systematic matrix (or the systematic portion of the base graph matrix) and Bₚ is the parity matrix (or the parity portion of the base graph matrix). The systematic matrix may be a submatrix of the base graph matrix that corresponds to the portion of the base graph associated with the information bits. In a systematic LDPC code, the information bits may be directly included in the encoded output without modification. The systematic matrix defines the connections between the information bits (variable nodes mapped to the information bits) and the check nodes. The systematic matrix may ensure that the information bits are part of the encoded communication in their original form, followed by the parity bits. The parity matrix may be a submatrix of the base graph matrix that corresponds to the portion of the base graph associated with the parity bits. The parity bits may be additional bits added to the information bits to ensure that a codeword (e.g., coded bits included in the encoded communication) satisfies the parity-check equations defined by the LDPC code. The parity matrix may define the connections between the parity bits (variable nodes mapped to the parity bits) and the check nodes. The first WCD 605 may use the connections indicated by the lifted graph (which is generated using the base graph) to determine or compute the parity bits based on the information bits, ensuring that the overall codeword adheres to the structure and properties of the LDPC code.

The base graph may satisfy the rank condition based on both the systematic matrix and the parity matrix satisfying the rank condition. In some aspects, the rank condition may indicate that both the systematic matrix and the parity matrix are to be full rank over the Galois field of two. The rank of the matrices may be evaluated over the Galois field of two because LDPC codes may be binary codes that operate over binary fields that use values of zero or one. In examples where the base graph is a binary graph includes only single edges between check nodes and variable nodes (e.g., where the base graph matrix is a binary matrix including only values of zero or one), the rank condition may indicate that both the systematic matrix and the parity matrix are to be full rank over the Galois field of two.

In some examples, the first WCD 605 may determine whether the base graph satisfies the rank condition. For example, the first WCD 605 may determine a rank of the systematic matrix. The rank of a matrix may be determined by the maximum number of linearly independent rows or columns within the matrix. The maximum number of linearly independent rows or columns within the matrix may be determined by performing row reduction to bring the matrix to a row echelon form or reduced row echelon form, and then counting the number of non-zero rows. As another example, the rank may be determined by determining the largest square submatrix with a non-zero determinant. The rank may be determined using modulo 2 operation, such as for addition, multiplication, solving for linear independence, row operations, or calculating rank, among other examples. Modulo 2 operation may be used to determine the rank over the Galois field of two. The first WCD 605 may determine whether the systematic matrix is full rank based on the rank and a smaller of the quantity of rows and the quantity of columns included in the systematic matrix. For example, full rank may indicate that the matrix (e.g., the systematic matrix or the parity matrix) has a maximum possible rank. In other words, full rank may indicate that the quantity of linearly independent rows (or columns) is equal to the smaller of the quantity of rows and the quantity of columns included in the systematic matrix. If the rank of the systematic matrix is equal to the smaller of the quantity of rows and the quantity of columns included in the systematic matrix, then the first WCD 605 may determine that the systematic matrix is full rank over the Galois field of two, and thereby satisfies the rank condition. The first WCD 605 may determine whether the parity matrix is full rank in a similar manner.

In some examples, the base graph may include one or more parallel edges or multi-edges (e.g., two or more connection between a given variable node and a given check node), such as in a punctured node of the base graph. For example, the base graph matrix may be a non-binary matrix. For example, the base graph matrix may include one or more entries with a value that is greater than one, such as two, three, or another integer value. In such examples, to evaluate whether the systematic matrix and the parity matrix are full rank, the first WCD 605 may convert the systematic matrix and the parity matrix to binary matrices, such as by using a modulo 2 operation. For example, the first WCD 605 may perform a modulo 2 operation for each entry included in the base graph matrix to obtain a binary matrix representing the base graph. As an example, the base graph, B, may be represented as B=[BₛBₚ], and the first WCD 605 may evaluate the rank condition using a first binary matrix (\tilde{B}ₛ) and a second binary matrix (\tilde{B}ₚ), where \tilde{B}ₛ=modulo(Bₛ,2) and \tilde{B}ₚ=modulo(Bₚ,2). The rank condition may be satisfied by: the first binary matrix (\tilde{B}ₛ), that is based on the first non-binary matrix (Bₛ), being full rank over the Galois field of order two; and the second binary matrix (\tilde{B}ₚ), that is based on the second non-binary matrix (Bₚ), being full rank over the Galois field of order two.

In some aspects, the first WCD 605 may evaluate the rank condition for the parity matrix using a determinant of the parity matrix. The first WCD 605 may determine the determinant of Bₚ in the real field, where the determinant is an integer number. For example, for a square matrix (such as the parity matrix), the first WCD 605 may determine the determinant via cofactor expansion or row reduction. For cofactor expansion, the first WCD 605 may determine the determinant by recursively expanding along a row or column, multiplying each element by the determinant of the submatrix that remains after removing the element's row and column, and applying alternating signs. In row reduction, the first WCD 605 may determine the determinant by transforming the parity matrix into an upper triangular form through a series of row operations, and the determinant may be the product of the diagonal elements. The first WCD 605 may determine whether the parity matrix satisfies the rank condition based on the determinant.

For example, the first WCD 605 may perform a modulo 2 operation on the determinant. If the modulo 2 of the determinant of the parity matrix is one, then the first WCD 605 may determine that the rank condition is satisfied. If the modulo 2 of the determinant of the parity matrix is zero, then the first WCD 605 may determine that the rank condition is not satisfied. As another example, if the determinant of the parity matrix is an odd number, then the first WCD 605 may determine that the rank condition is satisfied. If the determinant of the parity matrix is an even number, then the first WCD 605 may determine that the rank condition is not satisfied. For example, in the context of matrices over the Galois field of order two, the determinant of a matrix being one in modulo 2 indicates that the matrix is invertible. This is because a non-zero determinant indicates that the matrix has full rank and thus a unique inverse exists. Specifically, in the Galois field of order two, the determinant can only be zero or one. If the determinant is one (modulo 2), this indicates that the matrix is not singular and has an inverse, ensuring that the linear system represented by the matrix has a unique solution. Conversely, a determinant of zero would indicate that the matrix is singular and not invertible. Therefore, by using the determinant of the parity matrix, the first WCD 605 can determine whether the parity matrix has full rank and is therefore suitable for use for the LDPC code.

In some aspects, the parity matrix or the systematic may include one or more entries having a value greater than one. For example, the base graph matrix may be a non-binary matrix. In such examples, the systematic matrix and the parity matrix may be included in a modified base graph matrix that is based on the base graph. The modified base graph may include any entries having a value greater than one being set to a value of zero. For example, the first WCD 605 may modify the base graph matrix by setting any values greater than one to a value of zero to obtain the modified base graph matrix. The first WCD 605 may obtain the parity matrix and the systematic matrix from the modified base graph matrix. The first WCD 605 may determine whether the rank condition is satisfied using the parity matrix and the systematic matrix, such as by determining whether the parity matrix and the systematic matrix are full rank, or by using the determinant of the parity matrix, among other examples.

If the base graph satisfies the rank condition, then the first WCD 605 may use the base graph to generate a lifted graph (or PCM) for the LDPC code. For example, the first WCD 605 may generate, based at least in part on a lifting value and one or more cyclic shift values, a lifted graph using the base graph. The first WCD 605 may encode, using the lifted graph, the communication to obtain the encoded communication. If the base graph does not satisfy the rank condition, then the first WCD 605 may refrain from using the base graph to generate the lifted graph.

By the first WCD 605 encoding the communication using a lifted graph that is based on the base graph that satisfies the rank conditions, the first WCD 605 may ensure that the lifted graph is full rank over the Galois field of two regardless of the lifting parameters used to generate the lifted graph. This may reduce the complexity associated with ensuring that the lifted graph is full rank as new base graphs are configured or designed. By ensuring that the lifted graph is full rank as a result of the base graph satisfying the rank condition, the described techniques may reduce the risk of the first WCD 605 mapping different sets of information bits to the same codeword during the encoding process.

As shown by reference number 630, the first WCD 605 may provide or transmit, and the second WCD 610 may obtain or receive, the encoded communication. In some aspects, the first WCD 605 may provide or transmit, and the second WCD 610 may obtain or receive, the encoded communication via a shared channel or data channel, such as the PDSCH, the PUSCH, or the PSSCH. The encoded communication may include information bits and parity bits.

As shown by reference number 635, the second WCD 610 may decode the encoded communication to obtain the communication. For example, the second WCD 610 may decode the encoded communication to obtain one or more information bits. The second WCD 610 may decode the communication using an LDPC code. The LDPC code may be based on, or generated using, the base graph that satisfies the rank condition. This may ensure that the PCM, or lifted graph, of the LDPC code is full rank over the Galois field of order two, thereby reducing the likelihood of decoding errors that may be caused by the LDPC code producing two or more codewords that are mapped to the same coded bits.

The LDPC code may be constructed by lifting the base graph to create a larger PCM that maintains the degree distribution and structural properties of the base graph. The second WCD 610 may apply an iterative decoding algorithm, such as the belief propagation or sum-product algorithm, to decode the encoded communication. The iterative decoding algorithm may iteratively update the probabilities of the variable nodes (representing the information and parity bits) based on the parity-check equations defined by the PCM. The goal may be to converge to a solution where all parity-check equations are satisfied, indicating that the correct codeword has been found.

During each iteration, the second WCD 610 may exchange messages between the variable nodes and check nodes, updating the likelihoods of each bit being a 0 or 1. In this context, “messages” may refer to the probabilistic information passed between the nodes in the Tanner graph representation of the LDPC code. In each iteration, the second WCD 610 may use the variable nodes send messages to the connected check nodes, indicating the current likelihood that each bit is a 0 or 1 based on the received encoded communication and the information received from other check nodes in previous iterations. The second WCD 610 may use the check nodes to process these incoming messages to determine the likelihood that the parity-check equations are satisfied. Based on this information, the check nodes send updated messages back to the variable nodes, providing new likelihoods for each bit. The decoding process may continue until the algorithm converges to a valid codeword or a maximum number of iterations is reached. By ensuring that the PCM is full rank over GF(2), the LDPC code minimizes the risk of decoding errors and enhances the reliability of the communication. The rank condition on the base graph ensures that the codeword space is well-defined, preventing multiple codewords from mapping to the same set of coded bits and thereby improving the overall decoding performance. Once the decoding process is complete, the second WCD 610 may obtain the original information bits from the decoded codeword, thereby reconstructing the transmitted communication.

In some aspects, the second WCD 610 may determine that the base graph satisfies the rank condition, such as by using the systematic matrix and the parity matrix included in a base graph matrix representing the base graph. For example, in a similar manner as described in connection with the first WCD 605 and reference number 625, the second WCD 610 may determine whether both the systematic matrix and the parity matrix satisfy the rank condition in a similar manner as described in connection with the first WCD 605 and reference number 625. This ensures that the lifted graph used to construct the LDPC code is full rank regardless of the lifting operation performed by the second WCD 610.

As indicated above, FIG. 6 is provided as an example. Other examples may differ from what is described with respect to FIG. 6.

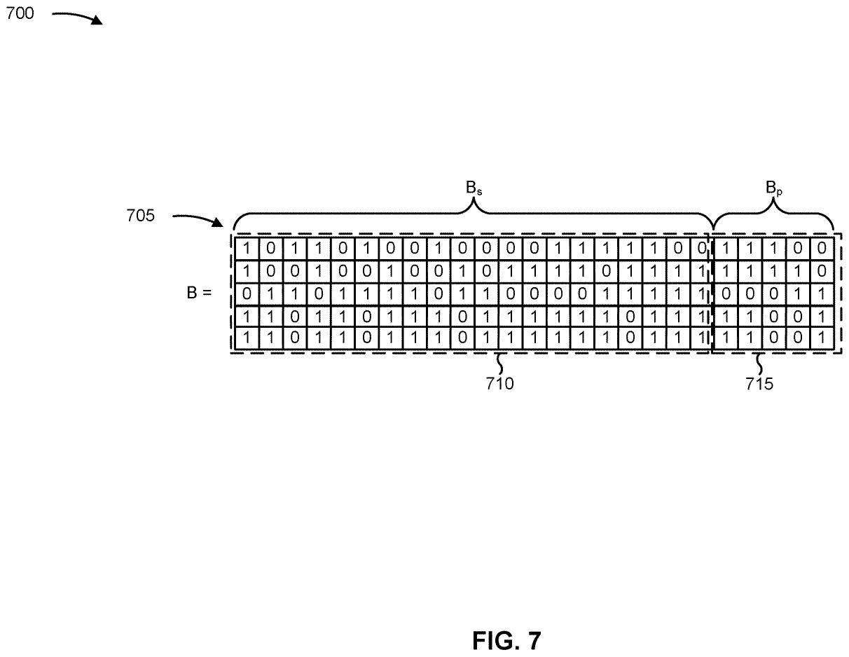

FIG. 7 is a diagram illustrating an example 700 of a base graph matrix 705 that satisfies a rank condition for LDPC codes. The base graph matrix 705 may represent a base graph similar to the LDPC base graph 320. The base graph matrix 705 may be a binary matrix. For example, the base graph matrix 705 may have entries that have values of either zero or one.

As shown in FIG. 7, the base graph matrix 705 (B) may include a systematic matrix 710 (or the systematic portion of the base graph matrix), Bₛ, and a parity matrix 715 (or the parity portion of the base graph matrix), Bₚ. The systematic matrix 710 may be a submatrix of the base graph matrix that corresponds to the portion of the base graph associated with the information bits. For example, the systematic matrix 710 may represent variable nodes to which the information bits are mapped. The parity matrix 715 may be associated with one or more parity bits. For example, the parity matrix 715 may represent variable nodes to which the parity bits are mapped.

The base graph represented by the base graph matrix 705 may satisfy a rank condition, such as the rank condition described in connection with FIG. 6. For example, the rank condition may be satisfied by both the systematic matrix 710 and the parity matrix 715. In some aspects, the rank condition may be satisfied by both the systematic matrix 710 and the parity matrix 715 being full rank over the Galois field of order two. In some examples, the rank condition may be satisfied in part by a modulo 2 of the determinant of the parity matrix 715 being a value of one.

As indicated above, FIG. 7 is provided as an example. Other examples may differ from what is described with respect to FIG. 7.

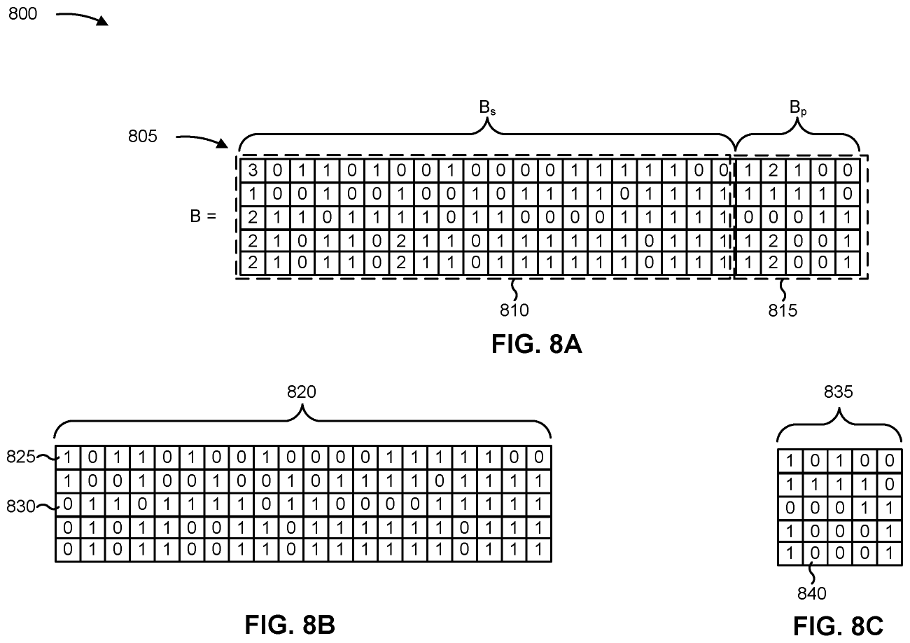

FIGS. 8A-8C are diagrams illustrating an example 800 of a base graph matrix 805 that satisfies a rank condition for LDPC codes. The base graph matrix 805 may represent a base graph similar to the LDPC base graph 320. As shown in FIG. 8A, the base graph matrix 805 may be a non-binary matrix. For example, the base graph matrix 805 may include one or more entries with a value greater than one, such as two, three, or another integer. As shown in FIG. 8A, the base graph matrix 805 (B) may include a systematic matrix 810 (or the systematic portion of the base graph matrix), Bₛ, and a parity matrix 815 (or the parity portion of the base graph matrix), Bₚ.

The base graph represented by the base graph matrix 805 may satisfy a rank condition, such as the rank condition described in connection with FIG. 6. To evaluate whether the base graph matrix 805 satisfies the rank condition, binary versions of the systematic matrix 810 and the parity matrix 815 may be generated. For example, a binary matrix 820 of the systematic matrix 810 is shown in FIG. 8B. The binary matrix 820 may be generated by applying a modulo 2 operation to each entry in the systematic matrix 810. For example, an entry 825 in the binary matrix 820 may have a value of one where the entry 825 original had a value of three in the base graph matrix 805 because a result of the modulo 2 operation on a value of three is one. Similarly, an entry 830 in the binary matrix 820 may have a value of zero where the entry 830 original had a value of two in the base graph matrix 805 because a result of the modulo 2 operation on a value of two is zero. A binary matrix 835 of the parity matrix 815 is shown in FIG. 8C. The binary matrix 835 may be generated by applying a modulo 2 operation to each entry in the parity matrix 815. For example, an entry 840 in the binary matrix 835 may have a value of zero where the entry 840 original had a value of two in the base graph matrix 805 because a result of the modulo 2 operation on a value of two is zero.

The rank condition may be satisfied by both the binary matrix 820 and the binary matrix 835 being full rank over the Galois field of order two. In some examples, the rank condition may be satisfied in part by a modulo 2 of the determinant of the binary matrix 820 being a value of one.

As indicated above, FIGS. 8A-8C are provided as examples. Other examples may differ from what is described with respect to FIGS. 8A-8C.

FIG. 9 is a diagram illustrating an example process 900 performed, for example, at a wireless communication device or an apparatus of a wireless communication device. Example process 900 is an example where the apparatus or the wireless communication device (e.g., the first WCD 605 or the WCD 170) performs operations associated with a rank condition for LDPC codes.

As shown in FIG. 9, in some aspects, process 900 may include encoding, using an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field (block 910). For example, the wireless communication device (e.g., using communication manager 150 or encoding component 1108, depicted in FIG. 11) may encode, using an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field, as described above.

As further shown in FIG. 9, in some aspects, process 900 may include providing, to a second wireless communication device, the encoded communication (block 920). For example, the wireless communication device (e.g., using communication manager 150 or transmission component 1104, depicted in FIG. 11) may provide, to a second wireless communication device, the encoded communication, as described above.

Process 900 may include additional aspects, such as any single aspect or any combination of aspects described below or in connection with one or more other processes described elsewhere herein.

In a first aspect, the systematic matrix is a first non-binary matrix and the parity matrix is a second non-binary matrix, and wherein the rank condition being satisfied includes a first binary matrix, that is based on the first non-binary matrix, being full rank over a Galois field of order two, and a second binary matrix, that is based on the second non-binary matrix, being full rank over the Galois field of order two.

In a second aspect, alone or in combination with the first aspect, the first binary matrix is full rank over the Galois field of order two based at least in part on a first rank of the first binary matrix being equal to or less than a first dimension of the first binary matrix, and wherein the second binary matrix is full rank over the Galois field of order two based at least in part on a second rank of the second binary matrix being equal to or less than a second dimension of the second binary matrix.

In a third aspect, alone or in combination with one or more of the first and second aspects, the rank condition being satisfied includes the systematic matrix being full rank over a Galois field of order two, and the parity matrix being full rank over the Galois field of order two.

In a fourth aspect, alone or in combination with one or more of the first through third aspects, the rank condition being satisfied includes a modulo 2 of a determinant of the parity matrix being a value of one.

In a fifth aspect, alone or in combination with one or more of the first through fourth aspects, the base graph includes one or more entries with a value greater than one, wherein the systematic matrix and the parity matrix are included in a modified base graph matrix that is based on the base graph, and wherein the modified base graph matrix includes one or more entries having a value of zero.

In a sixth aspect, alone or in combination with one or more of the first through fifth aspects, encoding the communication to obtain the encoded communication includes generating, based at least in part on a lifting value and one or more cyclic shift values, a lifted graph using the base graph, and encoding, using the lifted graph, the communication to obtain the encoded communication.

In a seventh aspect, alone or in combination with one or more of the first through sixth aspects, the base graph includes a single punctured node that is associated with multiple edges.

Although FIG. 9 shows example blocks of process 900, in some aspects, process 900 may include additional blocks, fewer blocks, different blocks, or differently arranged blocks than those depicted in FIG. 9. Additionally, or alternatively, two or more of the blocks of process 900 may be performed in parallel.

FIG. 10 is a diagram illustrating an example process 1000 performed, for example, at a wireless communication device or an apparatus of a wireless communication device. Example process 1000 is an example where the apparatus or the wireless communication device (e.g., the second WCD 610 or the WCD 175) performs operations associated with a rank condition for low-density parity check codes.

As shown in FIG. 10, in some aspects, process 1000 may include obtaining, from a second wireless communication device, an encoded communication (block 1010). For example, the wireless communication device (e.g., using communication manager 155 or reception component 1402, depicted in FIG. 14) may obtain, from a second wireless communication device, an encoded communication, as described above.

As further shown in FIG. 10, in some aspects, process 1000 may include decoding, using an LDPC code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field (block 1020). For example, the wireless communication device (e.g., using communication manager 155 or decoding component 1408, depicted in FIG. 14) may decode, using an LDPC code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field, as described above.

Process 1000 may include additional aspects, such as any single aspect or any combination of aspects described below or in connection with one or more other processes described elsewhere herein.

In a first aspect, the systematic matrix is a first non-binary matrix and the parity matrix is a second non-binary matrix, and wherein the rank condition being satisfied includes a first binary matrix, that is based on the first non-binary matrix, being full rank over a Galois field of order two, and a second binary matrix, that is based on the second non-binary matrix, being full rank over the Galois field of order two.

In a second aspect, alone or in combination with the first aspect, the first binary matrix is full rank over the Galois field of order two based at least in part on a first rank of the first binary matrix being equal to or less than a first dimension of the first binary matrix, and wherein the second binary matrix is full rank over the Galois field of order two based at least in part on a second rank of the second binary matrix being equal to or less than a second dimension of the second binary matrix.

In a third aspect, alone or in combination with one or more of the first and second aspects, the rank condition being satisfied includes the systematic matrix being full rank over a Galois field of order two, and the parity matrix being full rank over the Galois field of order two.

In a fourth aspect, alone or in combination with one or more of the first through third aspects, the rank condition being satisfied includes a modulo 2 of a determinant of the parity matrix being a value of one.

In a fifth aspect, alone or in combination with one or more of the first through fourth aspects, the base graph includes one or more entries with a value greater than one, wherein the systematic matrix and the parity matrix are included in a modified base graph matrix that is based on the base graph, and wherein the modified base graph matrix includes one or more entries having a value of zero.

In a sixth aspect, alone or in combination with one or more of the first through fifth aspects, decoding the communication to obtain the encoded communication includes generating, based at least in part on a lifting value and one or more cyclic shift values, a lifted graph using the base graph, and decoding, using the lifted graph, the communication to obtain the encoded communication.

In a seventh aspect, alone or in combination with one or more of the first through sixth aspects, the base graph includes a single punctured node that is associated with multiple edges.

Although FIG. 10 shows example blocks of process 1000, in some aspects, process 1000 may include additional blocks, fewer blocks, different blocks, or differently arranged blocks than those depicted in FIG. 10. Additionally, or alternatively, two or more of the blocks of process 1000 may be performed in parallel.

FIG. 11 is a diagram of an example apparatus 1100 for wireless communication. The apparatus 1100 may be a wireless communication device, or a wireless communication device may include the apparatus 1100. In some aspects, the apparatus 1100 includes a reception component 1102 and a transmission component 1104, which may be in communication with one another (for example, via one or more buses or one or more other components). As shown, the apparatus 1100 may communicate with another apparatus 1106 (such as a UE, a base station, or another wireless communication device) using the reception component 1102 and the transmission component 1104. As further shown, the apparatus 1100 may include the communication manager 150. The communication manager 150 may include one or more of an encoding component 1108, among other examples. The communication manager 150 may be included in, or implemented via, a processing system (for example, the processing system 180 described in connection with FIG. 1) of the wireless communication device.

In some aspects, the apparatus 1100 may be configured to perform one or more operations described herein in connection with FIGS. 8, 7, and 8A-8C. Additionally, or alternatively, the apparatus 1100 may be configured to perform one or more processes described herein, such as process 900 of FIG. 9, or a combination thereof. In some aspects, the apparatus 1100 or one or more components shown in FIG. 11 may include one or more components of the wireless communication device described in connection with FIG. 1. Additionally, or alternatively, one or more components shown in FIG. 11 may be implemented within one or more components described in connection with FIG. 1. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 1102 may receive communications, such as reference signals, control information, data communications, or a combination thereof, from the apparatus 1106. The reception component 1102 may provide received communications to one or more other components of the apparatus 1100. In some aspects, the reception component 1102 may perform signal processing on the received communications, and may provide the processed signals to the one or more other components of the apparatus 1100. In some aspects, the reception component 1102 may include one or more components of the wireless communication device described above in connection with FIG. 1, such as a radio, one or more RF chains, one or more transceivers, or one or more modems, each of which may in turn be coupled with one or more antennas of the wireless communication device.

The transmission component 1104 may transmit communications, such as reference signals, control information, data communications, or a combination thereof, to the apparatus 1106. In some aspects, one or more other components of the apparatus 1100 may generate communications and may provide the generated communications to the transmission component 1104 for transmission to the apparatus 1106. In some aspects, the transmission component 1104 may perform signal processing on the generated communications (such as filtering, amplification, modulation, digital-to-analog conversion, multiplexing, interleaving, mapping, or encoding, among other examples), and may transmit the processed signals to the apparatus 1106. In some aspects, the transmission component 1104 may include one or more components of the wireless communication device described above in connection with FIG. 1, such as a radio, one or more RF chains, one or more transceivers, or one or more modems, each of which may in turn be coupled with one or more antennas of the wireless communication device described in connection with FIG. 1. In some aspects, the transmission component 1104 may be co-located with the reception component 1102.

The encoding component 1108 may encode, using a an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field. The transmission component 1104 may provide, to the apparatus 1106, the encoded communication.

The number and arrangement of components shown in FIG. 11 are provided as an example. In practice, there may be additional components, fewer components, different components, or differently arranged components than those shown in FIG. 11. Furthermore, two or more components shown in FIG. 11 may be implemented within a single component, or a single component shown in FIG. 11 may be implemented as multiple, distributed components. Additionally, or alternatively, a set of (one or more) components shown in FIG. 11 may perform one or more functions described as being performed by another set of components shown in FIG. 11.

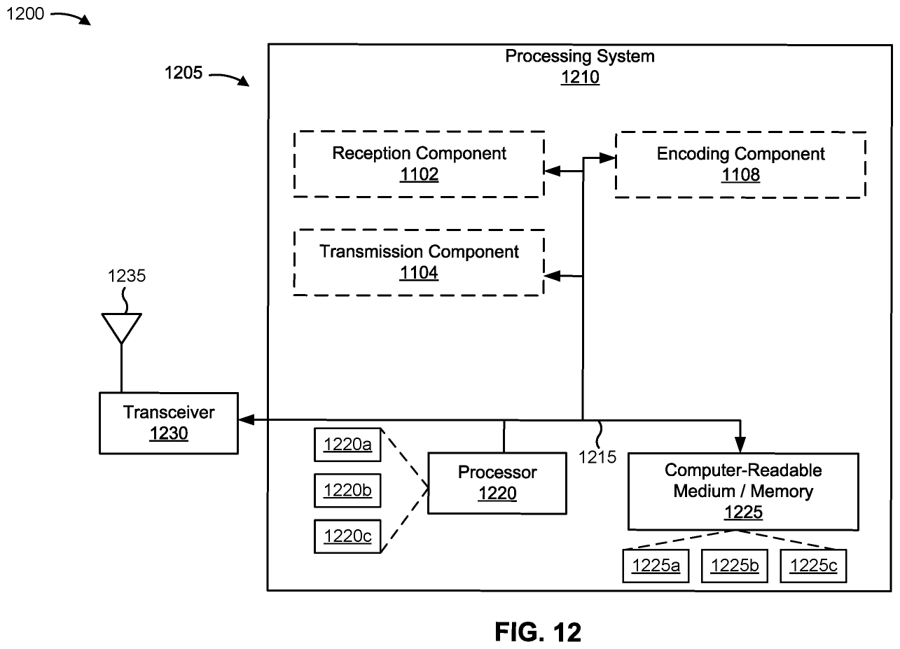

FIG. 12 is a diagram illustrating an example 1200 of a hardware implementation for an apparatus 1205 employing a processing system 1210. The apparatus 1205 may be a wireless communication device or may be at (e.g., included in) a wireless communication device. The processing system 1210 may be, or may be similar to, the processing system 180 of the WCD 170, the processing system 140 of the UE 120, or the processing system 145 of the network node 110 described in connection with FIG. 1.

The processing system 1210 may be implemented with a bus architecture, represented generally by the bus 1215. The bus 1215 may include any number of interconnecting buses and bridges depending on the specific application of the processing system 1210 and the overall design constraints. The bus 1215 links together various circuits including one or more processors or hardware components, represented by the processor (or processing circuitry) 1220, the illustrated components, and the computer-readable medium/memory (or memory circuitry) 1225. The processor 1220 may include multiple processors, such as processor 1220a, processor 1220b, and processor 1220c. The memory 1225 may include multiple memories, such as memory 1225a, memory 1225b, and memory 1225c The bus 1215 may also link various other circuits, such as timing sources, peripherals, voltage regulators, or power management circuits.

The processing system 1210 may be coupled to one or more transceivers 1230. A transceiver 1230 is coupled to one or more antennas 1235. The transceiver 1230 provides a means for communicating with various other apparatuses over a transmission medium. The transceiver 1230 receives a signal from the one or more antennas 1235, extracts information from the received signal, and provides the extracted information to the processing system 1210, specifically the reception component 1102. In addition, the transceiver 1230 receives information from the processing system 1210, specifically the transmission component 1104, and generates a signal to be applied to the one or more antennas 1235 based at least in part on the received information.

The processing system 1210 includes one or more processors 1220 coupled to a computer-readable medium/memory 1225. A processor 1220 is responsible for general processing, including the execution of software stored on the computer-readable medium/memory 1225. The software, when executed by the processor 1220, causes the processing system 1210 to perform the various functions described herein for any particular apparatus. The computer-readable medium/memory 1225 may also be used for storing data that is manipulated by the processor 1220 when executing software. The processing system further includes at least one of the illustrated components. The components may be software modules running in the processor 1220, resident/stored in the computer readable medium/memory 1225, one or more hardware modules coupled to the processor 1220, or some combination thereof.

In some aspects, the processing system 1210 may be a component of the WCD 170 or may be, may include, or may be included in the processing system 180 of the WCD 170 described in connection with FIG. 1. In some aspects, the apparatus 1205 for wireless communication includes means for means for encoding, using an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field; or means for providing, to a second wireless communication device, the encoded communication. The aforementioned means may be one or more of the aforementioned components of the apparatus 1100 or the processing system 1210 of the apparatus 1205 configured to perform the functions recited by the aforementioned means. As described elsewhere herein, the processing system 1210 may include one or more components of the processing system 180 of the WCD 170, the processing system 140 of the UE 120, or the processing system 145 of the network node 110 described in connection with FIG. 1. In one configuration, the aforementioned means may be a processing system (e.g., the processing system 180, the processing system 140, or the processing system 145) or one or more components of the processing system (e.g., the processing system 180, the processing system 140, or the processing system 145) configured to perform the functions or operations recited herein.

FIG. 12 is provided as an example. Other examples may differ from what is described in connection with FIG. 12.

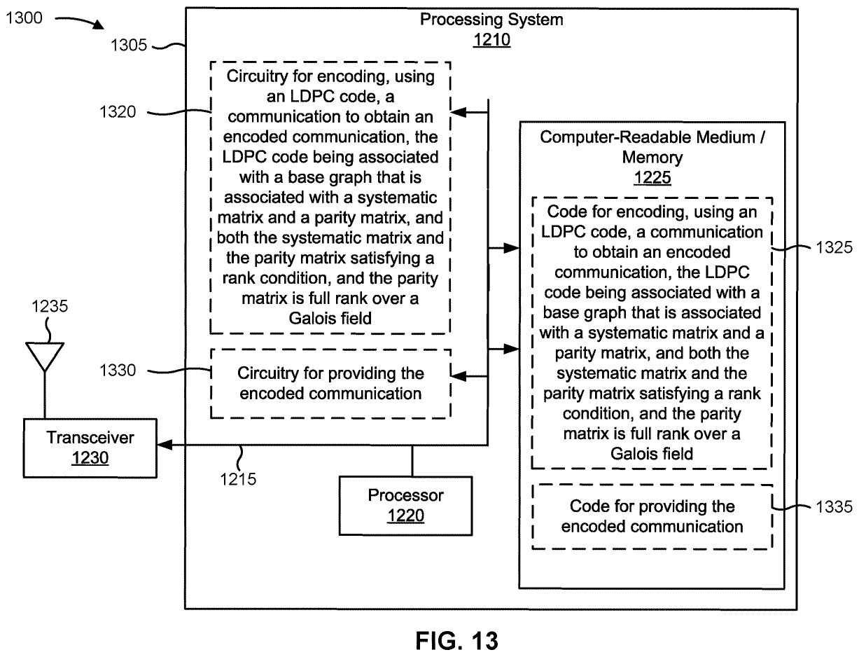

FIG. 13 is a diagram illustrating an example 1300 of an implementation of code and circuitry for an apparatus 1305. The apparatus 1305 may be a wireless communication device, or a wireless communication device may include the apparatus 1305.

As shown in FIG. 13, the apparatus 1305 may include circuitry for encoding, using an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field (circuitry 1320). For example, the circuitry 1320 may enable the apparatus 1305 to encode, using an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field.

As shown in FIG. 13, the apparatus 1305 may include, stored in computer-readable medium 1225, code for encoding, using an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field (code 1325). For example, the code 1325, when executed by processor 1220, may cause processor 1220 to encode, using an LDPC code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field.

As shown in FIG. 13, the apparatus 1305 may include circuitry for providing, to a second wireless communication device, the encoded communication (circuitry 1330). For example, the circuitry 1330 may enable the apparatus 1305 to provide or transmit the encoded communication.

As shown in FIG. 13, the apparatus 1305 may include, stored in computer-readable medium 1225, code for providing, to a second wireless communication device, the encoded communication (code 1335). For example, the code 1335, when executed by processor 1220, may cause processor 1220 to cause transceiver 1230 to provide or transmit the encoded communication.

FIG. 13 is provided as an example. Other examples may differ from what is described in connection with FIG. 13.

FIG. 14 is a diagram of an example apparatus 1400 for wireless communication. The apparatus 1400 may be a wireless communication device, or a wireless communication device may include the apparatus 1400. In some aspects, the apparatus 1400 includes a reception component 1402 and a transmission component 1404, which may be in communication with one another (for example, via one or more buses or one or more other components). As shown, the apparatus 1400 may communicate with another apparatus 1406 (such as a UE, a base station, or another wireless communication device) using the reception component 1402 and the transmission component 1404. As further shown, the apparatus 1400 may include the communication manager 155. The communication manager 155 may include one or more of a decoding component 1408, among other examples. The communication manager 155 may be included in, or implemented via, a processing system (for example, the process system 185, the processing system 140, or the processing system 145 described in connection with FIG. 1).

In some aspects, the apparatus 1400 may be configured to perform one or more operations described herein in connection with FIGS. 6, 7, and 8A-8C. Additionally, or alternatively, the apparatus 1400 may be configured to perform one or more processes described herein, such as process 1000 of FIG. 10, or a combination thereof. In some aspects, the apparatus 1400 or one or more components shown in FIG. 14 may include one or more components of the wireless communication device described in connection with FIG. 1. Additionally, or alternatively, one or more components shown in FIG. 14 may be implemented within one or more components described in connection with FIG. 1. Additionally, or alternatively, one or more components of the set of components may be implemented at least in part as software stored in one or more memories. For example, a component (or a portion of a component) may be implemented as instructions or code stored in a non-transitory computer-readable medium and executable by one or more controllers or one or more processors to perform the functions or operations of the component.

The reception component 1402 may receive communications, such as reference signals, control information, data communications, or a combination thereof, from the apparatus 1406. The reception component 1402 may provide received communications to one or more other components of the apparatus 1400. In some aspects, the reception component 1402 may perform signal processing on the received communications, and may provide the processed signals to the one or more other components of the apparatus 1400. In some aspects, the reception component 1402 may include one or more components of the wireless communication device described above in connection with FIG. 1, such as a radio, one or more RF chains, one or more transceivers, or one or more modems, each of which may in turn be coupled with one or more antennas of the wireless communication device.

The transmission component 1404 may transmit communications, such as reference signals, control information, data communications, or a combination thereof, to the apparatus 1406. In some aspects, one or more other components of the apparatus 1400 may generate communications and may provide the generated communications to the transmission component 1404 for transmission to the apparatus 1406. In some aspects, the transmission component 1404 may perform signal processing on the generated communications (such as filtering, amplification, modulation, digital-to-analog conversion, multiplexing, interleaving, mapping, or encoding, among other examples), and may transmit the processed signals to the apparatus 1406. In some aspects, the transmission component 1404 may include one or more components of the wireless communication device described above in connection with FIG. 1, such as a radio, one or more RF chains, one or more transceivers, or one or more modems, each of which may in turn be coupled with one or more antennas of the wireless communication device described in connection with FIG. 1. In some aspects, the transmission component 1404 may be co-located with the reception component 1402.

The reception component 1402 may obtain, from a second wireless communication device, an encoded communication. The decoding component 1408 may decode, using an LDPC code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field.

The number and arrangement of components shown in FIG. 14 are provided as an example. In practice, there may be additional components, fewer components, different components, or differently arranged components than those shown in FIG. 14. Furthermore, two or more components shown in FIG. 14 may be implemented within a single component, or a single component shown in FIG. 14 may be implemented as multiple, distributed components. Additionally, or alternatively, a set of (one or more) components shown in FIG. 14 may perform one or more functions described as being performed by another set of components shown in FIG. 14.

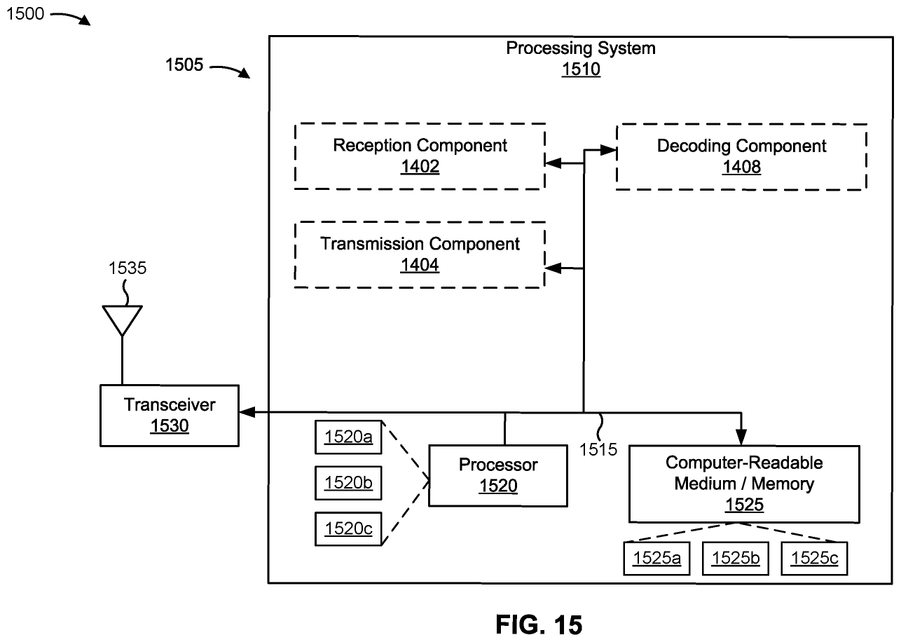

FIG. 15 is a diagram illustrating an example 1500 of a hardware implementation for an apparatus 1505 employing a processing system 1510. The apparatus 1505 may be a wireless communication device or may be at (e.g., included in) a wireless communication device. The processing system 1510 may be, or may be similar to, the processing system 185 of the WCD 175, the processing system 140 of the UE 120, or the processing system 145 of the network node 110 described in connection with FIG. 1.

The processing system 1510 may be implemented with a bus architecture, represented generally by the bus 1515. The bus 1515 may include any number of interconnecting buses and bridges depending on the specific application of the processing system 1510 and the overall design constraints. The bus 1515 links together various circuits including one or more processors or hardware components, represented by the processor (or processing circuitry) 1520, the illustrated components, and the computer-readable medium/memory (or memory circuitry) 1525. The processor 1520 may include multiple processors, such as processor 1520a, processor 1520b, and processor 1520c. The memory 1525 may include multiple memories, such as memory 1525a, memory 1525b, and memory 1525c The bus 1515 may also link various other circuits, such as timing sources, peripherals, voltage regulators, or power management circuits.

The processing system 1510 may be coupled to one or more transceivers 1530. A transceiver 1530 is coupled to one or more antennas 1535. The transceiver 1530 provides a means for communicating with various other apparatuses over a transmission medium. The transceiver 1530 receives a signal from the one or more antennas 1535, extracts information from the received signal, and provides the extracted information to the processing system 1510, specifically the reception component 1402. In addition, the transceiver 1530 receives information from the processing system 1510, specifically the transmission component 1404, and generates a signal to be applied to the one or more antennas 1535 based at least in part on the received information.

The processing system 1510 includes one or more processors 1520 coupled to a computer-readable medium/memory 1525. A processor 1520 is responsible for general processing, including the execution of software stored on the computer-readable medium/memory 1525. The software, when executed by the processor 1520, causes the processing system 1510 to perform the various functions described herein for any particular apparatus. The computer-readable medium/memory 1525 may also be used for storing data that is manipulated by the processor 1520 when executing software. The processing system further includes at least one of the illustrated components. The components may be software modules running in the processor 1520, resident/stored in the computer readable medium/memory 1525, one or more hardware modules coupled to the processor 1520, or some combination thereof.

In some aspects, the processing system 1510 may be a component of the WCD 175 or may be, may include, or may be included in the processing system 180 of the WCD 170 described in connection with FIG. 1. In some aspects, the apparatus 1505 for wireless communication includes means for means for obtaining, from a second wireless communication device, an encoded communication; or means for decoding, using a LDPC code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field. The aforementioned means may be one or more of the aforementioned components of the apparatus 1400 or the processing system 1510 of the apparatus 1505 configured to perform the functions recited by the aforementioned means. As described elsewhere herein, the processing system 1510 may include one or more components of a (e.g., the processing system 185, the processing system 140,, or the processing system 145) described in connection with FIG. 1. In one configuration, the aforementioned means may be the processing system 185, the processing system 140,, or the processing system 145 or one or more components of the processing system 185, the processing system 140, or the processing system 145 configured to perform the functions or operations recited herein.

FIG. 15 is provided as an example. Other examples may differ from what is described in connection with FIG. 15.

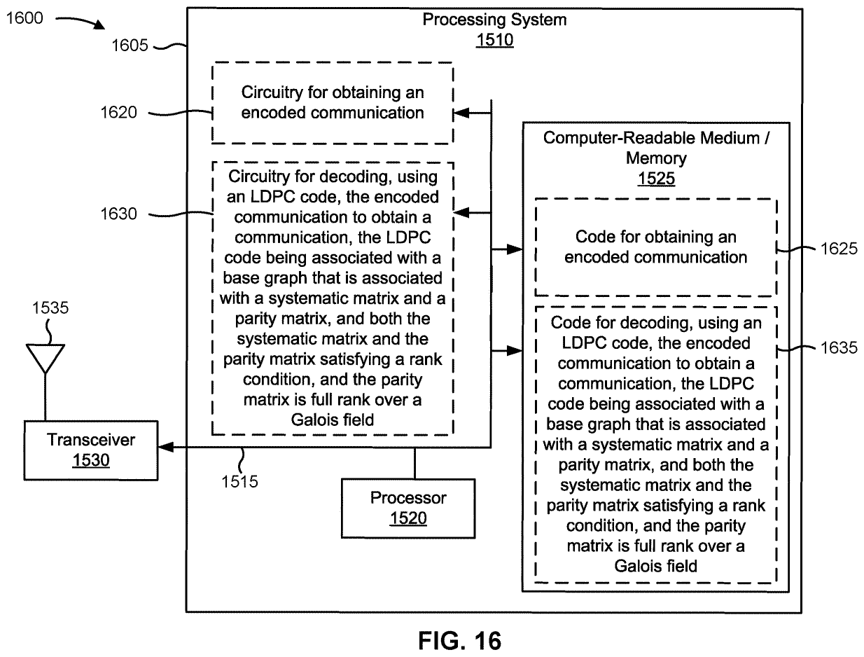

FIG. 16 is a diagram illustrating an example 1600 of an implementation of code and circuitry for an apparatus 1605. The apparatus 1605 may be a wireless communication device, or a wireless communication device may include the apparatus 1605.

As shown in FIG. 16, the apparatus 1605 may include circuitry for obtaining, from a second wireless communication device, an encoded communication (circuitry 1620). For example, the circuitry 1620 may enable the apparatus 1605 to obtain, from a second wireless communication device, an encoded communication.

As shown in FIG. 16, the apparatus 1605 may include, stored in computer-readable medium 1525, code for obtaining or receiving an encoded communication (code 1625). For example, the code 1625, when executed by processor 1520, may cause processor 1520 to cause transceiver 1530 to obtain, or receive, an encoded communication.

As shown in FIG. 16, the apparatus 1605 may include circuitry for decoding, using an LDPC code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field (circuitry 1630). For example, the circuitry 1630 may enable the apparatus 1605 to decode, using a LDPC code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field.

As shown in FIG. 16, the apparatus 1605 may include, stored in computer-readable medium 1525, code for decoding, using an LDPC code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field (code 1635). For example, the code 1635, when executed by processor 1520, may cause processor 1520 to decode, using an LDPC code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field.

FIG. 16 is provided as an example. Other examples may differ from what is described in connection with FIG. 16.

The following provides an overview of some Aspects of the present disclosure:

Aspect 1: A method of wireless communication performed at a first wireless communication device, comprising: encoding, using a low-density parity check (LDPC) code, a communication to obtain an encoded communication, the LDPC code being associated with a base graph that is associated with a systematic matrix and a parity matrix, and both the systematic matrix and the parity matrix satisfying a rank condition; and providing, to a second wireless communication device, the encoded communication.

Aspect 2: The method of Aspect 1, wherein the systematic matrix is a first non-binary matrix and the parity matrix is a second non-binary matrix, and wherein the rank condition being satisfied includes: a first binary matrix, that is based on the first non-binary matrix, being full rank over a Galois field of order two, and a second binary matrix, that is based on the second non-binary matrix, being full rank over the Galois field of order two.

Aspect 3: The method of Aspect 2, wherein the first binary matrix is full rank over the Galois field of order two based at least in part on a first rank of the first binary matrix being equal to or less than a first dimension of the first binary matrix, and wherein the second binary matrix is full rank over the Galois field of order two based at least in part on a second rank of the second binary matrix being equal to or less than a second dimension of the second binary matrix.

Aspect 4: The method of any of Aspects 1-3, wherein the rank condition being satisfied includes: the systematic matrix being full rank over a Galois field of order two, and the parity matrix being full rank over the Galois field of order two.

Aspect 5: The method of any of Aspects 1-4, wherein the rank condition being satisfied includes a modulo 2 of a determinant of the parity matrix being a value of one.

Aspect 6: The method of any of Aspects 1-5, wherein the base graph includes one or more entries with a value greater than one, wherein the systematic matrix and the parity matrix are included in a modified base graph matrix that is based on the base graph, and wherein the modified base graph matrix includes one or more entries having a value of zero.

Aspect 7: The method of any of Aspects 1-6, wherein encoding the communication to obtain the encoded communication comprises: generating, based at least in part on a lifting value and one or more cyclic shift values, a lifted graph using the base graph; and encoding, using the lifted graph, the communication to obtain the encoded communication.

Aspect 8: The method of any of Aspects 1-7, wherein the base graph includes a single punctured node that is associated with multiple edges.

Aspect 9: A method of wireless communication performed at a first wireless communication device, comprising: obtaining, from a second wireless communication device, an encoded communication; and decoding, using a low-density parity check (LDPC) code, the encoded communication to obtain a communication, the LDPC code being associated with a base graph that is associated with a systematic matrix and a parity matrix, and both the systematic matrix and the parity matrix satisfying a rank condition.

Aspect 10: The method of Aspect 9, wherein the systematic matrix is a first non-binary matrix and the parity matrix is a second non-binary matrix, and wherein the rank condition being satisfied includes: a first binary matrix, that is based on the first non-binary matrix, being full rank over a Galois field of order two, and a second binary matrix, that is based on the second non-binary matrix, being full rank over the Galois field of order two.

Aspect 11: The method of Aspect 10, wherein the first binary matrix is full rank over the Galois field of order two based at least in part on a first rank of the first binary matrix being equal to or less than a first dimension of the first binary matrix, and wherein the second binary matrix is full rank over the Galois field of order two based at least in part on a second rank of the second binary matrix being equal to or less than a second dimension of the second binary matrix.

Aspect 12: The method of any of Aspects 9-11, wherein the rank condition being satisfied includes: the systematic matrix being full rank over a Galois field of order two, and the parity matrix being full rank over the Galois field of order two.

Aspect 13: The method of any of Aspects 9-12, wherein the rank condition being satisfied includes a modulo 2 of a determinant of the parity matrix being a value of one.
Aspect 14: The method of any of Aspects 9-13, wherein the base graph includes one or more entries with a value greater than one, wherein the systematic matrix and the parity matrix are included in a modified base graph matrix that is based on the base graph, and wherein the modified base graph matrix includes one or more entries having a value of zero.
Aspect 15: The method of any of Aspects 9-14, wherein decoding the communication to obtain the encoded communication comprises: generating, based at least in part on a lifting value and one or more cyclic shift values, a lifted graph using the base graph; and decoding, using the lifted graph, the communication to obtain the encoded communication.

Aspect 16: The method of any of Aspects 9-15, wherein the base graph includes a single punctured node that is associated with multiple edges.

Aspect 1: A method of wireless communication performed at a first wireless communication device, comprising: encoding, using a low-density parity check (LDPC) code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field; and providing, to a second wireless communication device, the encoded communication.

Aspect 2: The method of Aspect 1, wherein the systematic matrix is a first non-binary matrix and the parity matrix is a second non-binary matrix, and wherein the rank condition being satisfied includes: a first binary matrix, that is based on the first non-binary matrix, being full rank over a Galois field of order two, and a second binary matrix, that is based on the second non-binary matrix, being full rank over the Galois field of order two.

Aspect 3: The method of Aspect 2, wherein the first binary matrix is full rank over the Galois field of order two based at least in part on a first rank of the first binary matrix being equal to or less than a first dimension of the first binary matrix, and wherein the second binary matrix is full rank over the Galois field of order two based at least in part on a second rank of the second binary matrix being equal to or less than a second dimension of the second binary matrix.

Aspect 4: The method of any of Aspects 1-3, wherein the rank condition being satisfied includes: the systematic matrix being full rank over a Galois field of order two, and the parity matrix being full rank over the Galois field of order two.

Aspect 5: The method of any of Aspects 1-4, wherein the rank condition being satisfied includes a modulo 2 of a determinant of the parity matrix being a value of one.

Aspect 6: The method of any of Aspects 1-5, wherein the base graph includes one or more entries with a value greater than one, wherein the systematic matrix and the parity matrix are included in a modified base graph matrix that is based on the base graph, and wherein the modified base graph matrix includes one or more entries having a value of zero.

Aspect 7: The method of any of Aspects 1-6, wherein encoding the communication to obtain the encoded communication comprises: generating, based at least in part on a lifting value and one or more cyclic shift values, a lifted graph using the base graph; and encoding, using the lifted graph, the communication to obtain the encoded communication.

Aspect 8: The method of any of Aspects 1-7, wherein the base graph includes a single punctured node that is associated with multiple edges.

Aspect 9: A method of wireless communication performed at a first wireless communication device, comprising: obtaining, from a second wireless communication device, an encoded communication; and decoding, using a low-density parity check (LDPC) code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field.

Aspect 10: The method of Aspect 9, wherein the systematic matrix is a first non-binary matrix and the parity matrix is a second non-binary matrix, and wherein the rank condition being satisfied includes: a first binary matrix, that is based on the first non-binary matrix, being full rank over a Galois field of order two, and a second binary matrix, that is based on the second non-binary matrix, being full rank over the Galois field of order two.

Aspect 11: The method of Aspect 10, wherein the first binary matrix is full rank over the Galois field of order two based at least in part on a first rank of the first binary matrix being equal to or less than a first dimension of the first binary matrix, and wherein the second binary matrix is full rank over the Galois field of order two based at least in part on a second rank of the second binary matrix being equal to or less than a second dimension of the second binary matrix.

Aspect 12: The method of any of Aspects 9-11, wherein the rank condition being satisfied includes: the systematic matrix being full rank over a Galois field of order two, and the parity matrix being full rank over the Galois field of order two.

Aspect 13: The method of any of Aspects 9-12, wherein the rank condition being satisfied includes a modulo 2 of a determinant of the parity matrix being a value of one.

Aspect 14: The method of any of Aspects 9-13, wherein the base graph includes one or more entries with a value greater than one, wherein the systematic matrix and the parity matrix are included in a modified base graph matrix that is based on the base graph, and wherein the modified base graph matrix includes one or more entries having a value of zero.

Aspect 15: The method of any of Aspects 9-14, wherein decoding the communication to obtain the encoded communication comprises: generating, based at least in part on a lifting value and one or more cyclic shift values, a lifted graph using the base graph; and decoding, using the lifted graph, the communication to obtain the encoded communication.

Aspect 16: The method of any of Aspects 9-15, wherein the base graph includes a single punctured node that is associated with multiple edges.

Aspect 17: A method of wireless communication performed at a first wireless communication device, comprising: encoding, using a low-density parity check (LDPC) code, a communication to obtain an encoded communication, the LDPC code being associated with a base graph that is associated with a systematic matrix and a parity matrix, both the systematic matrix and the parity matrix satisfying a rank condition, and the parity matrix is full rank over a Galois field; and providing, to a second wireless communication device, the encoded communication.

Aspect 18: The method of Aspect 17, wherein the systematic matrix is a first non-binary matrix and the parity matrix is a second non-binary matrix, and wherein the rank condition being satisfied includes: a first binary matrix, that is based on the first non-binary matrix, being full rank over a Galois field of order two, and a second binary matrix, that is based on the second non-binary matrix, being full rank over the Galois field of order two.

Aspect 19: The method of Aspect 18, wherein the first binary matrix is full rank over the Galois field of order two based at least in part on a first rank of the first binary matrix being equal to or less than a first dimension of the first binary matrix, and wherein the second binary matrix is full rank over the Galois field of order two based at least in part on a second rank of the second binary matrix being equal to or less than a second dimension of the second binary matrix.

Aspect 20: The method of any of Aspects 17-19, wherein the rank condition being satisfied includes: the systematic matrix being full rank over a Galois field of order two, and the parity matrix being full rank over the Galois field of order two.

Aspect 21: The method of any of Aspects 17-20, wherein the rank condition being satisfied includes a modulo 2 of a determinant of the parity matrix being a value of one.

Aspect 22: The method of any of Aspects 17-21, wherein the base graph includes one or more entries with a value greater than one, wherein the systematic matrix and the parity matrix are included in a modified base graph matrix that is based on the base graph, and wherein the modified base graph matrix includes one or more entries having a value of zero.

Aspect 23: The method of any of Aspects 17-22, wherein encoding the communication to obtain the encoded communication comprises: generating, based at least in part on a lifting value and one or more cyclic shift values, a lifted graph using the base graph; and encoding, using the lifted graph, the communication to obtain the encoded communication.

Aspect 24: The method of any of Aspects 17-23, wherein the base graph includes a single punctured node that is associated with multiple edges.

Aspect 25: A method of wireless communication performed at a first wireless communication device, comprising: obtaining, from a second wireless communication device, an encoded communication; and decoding, using a low-density parity check (LDPC) code, the encoded communication to obtain a communication, the LDPC code being associated with a base graph that is associated with a systematic matrix and a parity matrix, both the systematic matrix and the parity matrix satisfying a rank condition, and the parity matrix is full rank over a Galois field.

Aspect 26: The method of Aspect 25, wherein the systematic matrix is a first non-binary matrix and the parity matrix is a second non-binary matrix, and wherein the rank condition being satisfied includes: a first binary matrix, that is based on the first non-binary matrix, being full rank over a Galois field of order two, and a second binary matrix, that is based on the second non-binary matrix, being full rank over the Galois field of order two.

Aspect 27: The method of Aspect 26, wherein the first binary matrix is full rank over the Galois field of order two based at least in part on a first rank of the first binary matrix being equal to or less than a first dimension of the first binary matrix, and wherein the second binary matrix is full rank over the Galois field of order two based at least in part on a second rank of the second binary matrix being equal to or less than a second dimension of the second binary matrix.

Aspect 28: The method of any of Aspects 25-27, wherein the rank condition being satisfied includes: the systematic matrix being full rank over a Galois field of order two, and the parity matrix being full rank over the Galois field of order two.

Aspect 29: The method of any of Aspects 25-28, wherein the rank condition being satisfied includes a modulo 2 of a determinant of the parity matrix being a value of one.

Aspect 30: The method of any of Aspects 25-29, wherein the base graph includes one or more entries with a value greater than one, wherein the systematic matrix and the parity matrix are included in a modified base graph matrix that is based on the base graph, and wherein the modified base graph matrix includes one or more entries having a value of zero.

Aspect 31: The method of any of Aspects 25-30, wherein decoding the communication to obtain the encoded communication comprises: generating, based at least in part on a lifting value and one or more cyclic shift values, a lifted graph using the base graph; and decoding, using the lifted graph, the communication to obtain the encoded communication.

Aspect 32: The method of any of Aspects 25-31, wherein the base graph includes a single punctured node that is associated with multiple edges.

Aspect 33: An apparatus for wireless communication at a device, the apparatus comprising one or more processors; one or more memories coupled with the one or more processors; and instructions stored in the one or more memories and executable by the one or more processors to cause the apparatus to perform the method of one or more of Aspects 1-32.

Aspect 34: An apparatus for wireless communication at a device, the apparatus comprising one or more memories and one or more processors coupled to the one or more memories, the one or more processors configured to cause the device to perform the method of one or more of Aspects 1-32.

Aspect 35: An apparatus for wireless communication, the apparatus comprising at least one means for performing the method of one or more of Aspects 1-32.

Aspect 36: A non-transitory computer-readable medium storing code for wireless communication, the code comprising instructions executable by one or more processors to perform the method of one or more of Aspects 1-32.

Aspect 37: A non-transitory computer-readable medium storing a set of instructions for wireless communication, the set of instructions comprising one or more instructions that, when executed by one or more processors of a device, cause the device to perform the method of one or more of Aspects 1-32.

Aspect 38: A device for wireless communication, the device comprising a processing system that includes one or more processors and one or more memories coupled with the one or more processors, the processing system configured to cause the device to perform the method of one or more of Aspects 1-32.

Aspect 39: An apparatus for wireless communication at a device, the apparatus comprising one or more memories and one or more processors coupled to the one or more memories, the one or more processors individually or collectively configured to cause the device to perform the method of one or more of Aspects 1-32.

Aspect 40: A device comprising a processing system that includes one or more processors and one or more code-storing memories coupled with the one or more processors, the processing system configured to cause the device to perform the method of one or more of Aspects 1-32.

Aspect 41: A device comprising a processing system that includes processor circuitry and code-storing memory circuitry, the processing system configured to cause the device to perform the method of one or more of Aspects 1-32.

Aspect 42: An apparatus for wireless communication at a wireless communication device, comprising: a processing system that includes processor circuitry and memory circuitry that stores code and is coupled with the processor circuitry, the processing system configured to cause the wireless communication device to perform the method of one or more of Aspects 1-32.

It will be apparent that systems or methods described herein may be implemented in different forms of hardware or a combination of hardware and software. A component being configured to perform a function means that the component has a capability to perform the function, and does not require the function to be actually performed by the component, unless noted otherwise.

As used herein, the term “determine” or “determining” can encompass one or more of a wide variety of actions. For example, “determining” can include one or more of calculating, computing, processing, deriving, detecting, estimating, investigating, looking up, inferring, ascertaining, measuring, resolving, selecting, choosing, obtaining, identifying, interpreting, demodulating, decoding, reading, establishing, forming or generating, among other examples. In some such examples, determining can involve a processor performing some type of calculating, computing, deriving, estimating, inferring, ascertaining, resolving, predicting or other processing to obtain one or more numerical values, sets, elements or other information or results. In some other such examples, determining can involve a processor identifying, looking up, investigating or otherwise obtaining some type of value, set, element or other information or result from a table, a data structure, a database or other memory device or location. In some other such examples, determining can involve a processor identifying, interpreting, demodulating, decoding, detecting, reading or otherwise obtaining some type of value, set, element or other information or result signaled in, for example, a received wireless packet. In some other such examples, determining can involve a processor selecting or choosing one or more values, sets, elements or other information or results from a larger set of values, sets elements or other information or results. In some other such examples, determining can involve a processor performing a measurement, such as on a received signal.

As used herein, the articles “a” and “an” are intended to refer to one or more items and may be used interchangeably with “one or more” or “at least one.” As used herein, a phrase referring to “at least one of” or “one or more of” a list of items refers to any combination of those items, including single members. As an example, “at least one of: a, b, or c” is intended to cover: a, b, c, a-b, a-c, b-c, and a-b-c. Additionally, as used herein, a phrase referring to “a” or “an” element refers to one or more of such elements acting individually or collectively to perform the recited function(s). Additionally, as used herein, a “set” can refer to one or more items, and a “subset” can refer to a whole set or less than the whole set, but not an empty set. “Set,” “group,” and similar terms are intended to include one or more items and may be used interchangeably with “one or more.” Furthermore, as used herein, the term “or” is intended to be interpreted in the inclusive sense (such as when referring to a series) and may be used interchangeably with “and/or,” unless otherwise explicitly indicated (for example, if used in conjunction with “either” or “only one of”). For example, “A or B” may include A only, B only, or a combination of A and B. Also, as used herein, the terms “has,” “have,” “having,” “comprise,” “comprising,” “include” and “including,” and derivatives thereof or similar terms are intended to be open-ended terms that do not limit an element that they modify (for example, an element “having” A also may have B).

As used herein, the phrase “associated with” is intended to be interpreted in the inclusive sense, unless otherwise explicitly indicated. For example, the phrase “associated with” is not to be construed as a reference to a closed set of conditions, factors, criteria, elements, components, or actions, among other examples. Specifically, unless a phrase refers to “associated with only ‘a,’” or the equivalent in context, whatever it is that is “associated with ‘a,’” may be associated with “a” alone or associated with a combination of “a” and one or more other conditions, factors, criteria, elements, components, or actions, among other examples.

As used herein, “satisfying a threshold” may, depending on the context, refer to a value being greater than the threshold, greater than or equal to the threshold, less than the threshold, less than or equal to the threshold, equal to the threshold, or not equal to the threshold, among other examples.

Even though particular combinations of features are recited in the claims or disclosed in the specification, these combinations are not intended to limit the scope of all aspects described herein. Many of these features may be combined in ways not specifically recited in the claims or disclosed in the specification. The disclosure of various aspects includes each dependent claim in combination with every other claim in the claim set.

What is claimed is:

1. An apparatus at a first wireless communication device, comprising:
one or more memories; and
one or more processors coupled with the one or more memories and configured to cause the first wireless communication device to:
encode, using a low-density parity check (LDPC) code, a communication to obtain an encoded communication, wherein the LDPC code is associated with a base graph that is associated with a systematic matrix and a parity matrix, wherein both the systematic matrix and the parity matrix satisfy a rank condition, and wherein the parity matrix is full rank over a Galois field; and
provide, to a second wireless communication device, the encoded communication.

2. The apparatus of claim 1, wherein the systematic matrix is a first non-binary matrix and the parity matrix is a second non-binary matrix, and wherein the rank condition is satisfied by:
a first binary matrix that is based on the first non-binary matrix, wherein the first binary matrix is full rank over the Galois field, wherein the Galois field is of order two, and a second binary matrix that is based on the second non-binary matrix, wherein the second binary matrix is full rank over the Galois field.

3. The apparatus of claim 2, wherein the first binary matrix is full rank over the Galois field based at least in part on a first rank of the first binary matrix, wherein the first rank is equal to or less than a first dimension of the first binary matrix, and wherein the second binary matrix is full rank over the Galois field based at least in part on a second rank of the second binary matrix, wherein the second rank is equal to or less than a second dimension of the second binary matrix.

4. The apparatus of claim 1, wherein the rank condition is satisfied by:
the systematic matrix, wherein the systematic matrix is full rank over the Galois field, wherein the Galois field is of order two, and
the parity matrix, wherein the parity matrix is full rank over the Galois field.

5. The apparatus of claim 1, wherein the rank condition is satisfied by a modulo 2 of a determinant of the parity matrix, wherein the modulo 2 of the determinant is a value of one.

6. The apparatus of claim 1, wherein the base graph includes one or more entries with a value greater than one, wherein the systematic matrix and the parity matrix are included in a modified base graph matrix that is based on the base graph, and wherein the modified base graph matrix has one or more entries of a value of zero.

7. The apparatus of claim 1, wherein to encode the communication to obtain the encoded communication, the one or more processors are configured to cause the first wireless communication device to:
generate, based at least in part on a lifting value and one or more cyclic shift values, a lifted graph using the base graph; and
encode, using the lifted graph, the communication to obtain the encoded communication.

8. The apparatus of claim 1, wherein the base graph includes a single punctured node that is associated with multiple edges.

9. An apparatus at a first wireless communication device, comprising:
one or more memories; and
one or more processors coupled with the one or more memories and configured to cause the first wireless communication device to:
obtain, from a second wireless communication device, an encoded communication; and
decode, using a low-density parity check (LDPC) code, the encoded communication to obtain a communication, wherein the LDPC code is associated with a base graph that is associated with a systematic matrix and a parity matrix, wherein both the systematic matrix and the parity matrix satisfy a rank condition, and wherein the parity matrix is full rank over a Galois field.

10. The apparatus of claim 9, wherein the systematic matrix is a first non-binary matrix and the parity matrix is a second non-binary matrix, and wherein the rank condition is satisfied by:
a first binary matrix that is based on the first non-binary matrix, wherein the first binary matrix is full rank over the Galois field, wherein the Galois field is of order two, and a second binary matrix that is based on the second non-binary matrix, wherein the second binary matrix is full rank over the Galois field.

11. The apparatus of claim 10, wherein the first binary matrix is full rank over the Galois field based at least in part on a first rank of the first binary matrix, wherein the first rank is equal to or less than a first dimension of the first binary matrix, and wherein the second binary matrix is full rank over the Galois field based at least in part on a second rank of the second binary matrix, wherein the second rank is equal to or less than a second dimension of the second binary matrix.

12. The apparatus of claim 9, wherein the rank condition is satisfied by:
the systematic matrix, wherein the systematic matrix is full rank over the Galois field, wherein the Galois field is of order two, and
the parity matrix, wherein the parity matrix is full rank over the Galois field.

13. The apparatus of claim 9, wherein the rank condition is satisfied by a modulo 2 of a determinant of the parity matrix, wherein the modulo 2 of the determinant is a value of one.

14. The apparatus of claim 9, wherein the base graph includes one or more entries with a value greater than one, wherein the systematic matrix and the parity matrix are included in a modified base graph matrix that is based on the base graph, and wherein the modified base graph matrix has one or more entries of a value of zero.

15. The apparatus of claim 9, wherein to decode the communication to obtain the encoded communication, the one or more processors are configured to cause the first wireless communication device to:
generate, based at least in part on a lifting value and one or more cyclic shift values, a lifted graph using the base graph; and
decode, using the lifted graph, the communication to obtain the encoded communication.

16. The apparatus of claim 9, wherein the base graph includes a single punctured node that is associated with multiple edges.

17. A method of wireless communication performed at a first wireless communication device, comprising:
encoding, using a low-density parity check (LDPC) code, a communication to obtain an encoded communication, the LDPC code being associated with a base graph that is associated with a systematic matrix and a parity matrix, wherein both the systematic matrix and the parity matrix satisfy a rank condition, and wherein the parity matrix is full rank over a Galois field; and
providing, to a second wireless communication device, the encoded communication.

18. The method of claim 17, wherein the systematic matrix is a first non-binary matrix and the parity matrix is a second non-binary matrix, and wherein the rank condition being satisfied includes:
a first binary matrix, that is based on the first non-binary matrix, being full rank over the Galois field, wherein the Galois field is of order two, and
a second binary matrix, that is based on the second non-binary matrix, being full rank over the Galois field.

19. The method of claim 18, wherein the first binary matrix is full rank over the Galois field based at least in part on a first rank of the first binary matrix being equal to or less than a first dimension of the first binary matrix, and wherein the second binary matrix is full rank over the Galois field based at least in part on a second rank of the second binary matrix being equal to or less than a second dimension of the second binary matrix.

20. The method of claim 17, wherein the rank condition being satisfied includes:
the systematic matrix being full rank over a Galois field of order two, and
the parity matrix being full rank over the Galois field of order two.
